(19) United States
(12) Patent Application Publication
(10) Pub. No.: US 2008/0116993 A1
(43) Pub. Date: May 22, 2008

(54) Piezoelectric Filter, and Duplexer and Communications Apparatus Using the Same

(76) Inventors: Takehiko Yamakawa, Osaka (JP); Hiroyuki Nakamura, Osaka (JP); Keiji Onishi, Osaka (JP)

Correspondence Address: WENDEROTH, LIND & PONACK L.L.P., 2033 K. STREET, NW, SUITE 800, WASHINGTON, DC, 20006, US

(21) Appl. No.: 11/883,940

(22) PCT Filed: Feb. 21, 2006
(86) PCT No.: PCT/JP06/03539

§ 371 Date: Aug. 8, 2007

(30) Foreign Application Priority Data
Feb. 28, 2005 (JP) 2005-054897
Feb. 28, 2005 (JP) 2005-054898

(51) Int. Cl. H03H 9/54; H03H 7/38; H03H 9/64

(52) U.S. Cl. 333/124; 333/133; 333/32; 333/193

(57) ABSTRACT

A piezoelectric filter which has a small circuit scale and device size and can reduce a loss, is provided. The piezoelectric filter (1) has an input impedance smaller than an output impedance. The piezoelectric filter (1) comprises an input terminal (101a), an output terminal (101b), series piezoelectric resonators (102a, 102b, 102c), and parallel piezoelectric resonators (103a, 103b, 103c). Among the parallel piezoelectric resonators (103a, 103b, 103c), on an equivalent circuit, a capacitance of a first parallel piezoelectric resonator (103a) close to the input terminal (101a) side is larger than a capacitance of a second parallel piezoelectric resonator (103c) close to the output terminal (101b) side.

### TECHNICAL FIELD

The present invention relates to a filter for use in a wireless circuit of a mobile communications terminal, such as a mobile telephone, a wireless LAN, or the like. More particularly, the present invention relates to a piezoelectric filter composed of a piezoelectric material.

### BACKGROUND ART

A small size, a light weight, and high performance are required for parts incorporated in electronic apparatuses, such as a mobile telephone and the like. An example of a filter satisfying such requirements is a piezoelectric filter composed of a piezoelectric material.

Hereinafter, a conventional radio circuit of a piezoelectric filter and peripheral circuitry thereof will be described with reference to the accompanying drawings.

FIG. 28 is a block diagram illustrating a conventional peripheral circuit comprising a piezoelectric filter. In FIG. 28, the conventional peripheral circuit comprises an amplifier 2801, a matching circuit 2802, and a piezoelectric filter 2803. Typically, in a radio communications circuit employing a high frequency signal, the characteristic impedance is 50 ohms. Therefore, the piezoelectric filter 2803 is designed to have 50 ohms at the input side and the output side thereof. However, in the amplifier 2801, typically, the output side thereof has an impedance which is different from 50 ohms. Therefore, in order to reduce a loss degradation due to a mismatch, the matching circuit 2802 is provided between the output side of the amplifier 2801 and the input side of the piezoelectric filter 2803.

Also, conventionally, a filter has been disclosed in which the input-side impedance is different from the output-side impedance in order to prevent a mismatch between the input and the output (see, for example, Patent Document 1). FIG. 29 is a diagram illustrating a conventional filter in which the input-side impedance is different from the output-side impedance. In the conventional filter of FIG. 29, the input and output impedances are different from each other, so that a matching circuit can be omitted between the amplifier and the piezoelectric filter. The filter of FIG. 29 includes an input terminal 2901, an output terminal 2902, an input capacitance 2903, an output capacitance 2904, an interstage capacitance 2905, and dielectric resonators 2906 and 2907. In order to cause the input impedance to be larger than the output impedance, the input capacitance 2903 is larger than the output capacitance 2904. The dielectric resonator 2906 is designed to have a resonance frequency which is higher than that of the dielectric resonator 2907.

Patent Document 1: Japanese Patent Laid-Open Publication No. 11-88011

However, the conventional peripheral circuit structure of FIG. 28 has a large circuit scale due to the matching circuit, and therefore, is disadvantageous in terms of miniaturization and loss reduction of the device.

In addition, in the conventional filter structure of FIG. 29, the interstage capacitance is determined based on the bandwidth of the filter. Therefore, a mismatch between the interstage capacitance and the input capacitance or a mismatch between the interstage capacitance and the output capacitance disadvantageously increases a loss.

Therefore, an object of the present invention is to provide a piezoelectric filter capable of reducing a circuit scale, a device size, and a loss.

### DISCLOSURE OF THE INVENTION

To achieve the above objects, the present invention has the following aspects. The present invention provides a piezoelectric filter comprising an input terminal, an output terminal, one or more series piezoelectric resonators connected in series between the input terminal and the output terminal, and two or more parallel piezoelectric resonators connected in parallel between the input terminal and the output terminal. Among the two or more parallel piezoelectric resonators, on an equivalent circuit, a capacitance of a first parallel piezoelectric resonator closest to the input terminal side is larger than a capacitance of a second parallel piezoelectric resonator closest to the output terminal side.

Preferably, the two or more parallel piezoelectric resonators may have capacitances which are successively decreased toward the output terminal side in order of distance from the input terminal side, smallest first, on an equivalent circuit.

Preferably, the number of the series piezoelectric resonators may be two or more, and among the two or more series piezoelectric resonators, on an equivalent circuit, a capacitance of a first series piezoelectric resonator closest to the input terminal side may be larger than a capacitance of a second series piezoelectric resonator closest to the output terminal side.

The present invention also provides a duplexer comprising an antenna terminal, a transmitting side terminal, a receiving side terminal, a transmitting filter connected between the antenna terminal and the transmitting side terminal, and a receiving filter connected between the antenna terminal and the receiving side terminal. At least one of the transmitting filter and the receiving filter is a piezoelectric filter in which an input impedance is smaller than an output impedance. The piezoelectric filter comprises an input terminal, an output terminal, one or more series piezoelectric resonators connected in series between the input terminal and the output terminal, and two or more parallel piezoelectric resonators connected in parallel between the input terminal and the output terminal. Among the two or more parallel piezoelectric resonators, on an equivalent circuit, a capacitance of a first parallel piezoelectric resonator closest to the input terminal side is larger than a capacitance of a second parallel piezoelectric resonator closest to the output terminal side.

The present invention also provides a communications apparatus comprising a transmitting-side power amplifier, an antenna, and a transmitting filter connected between the antenna and the power amplifier. The transmitting filter is a piezoelectric filter whose input impedance is conjugate to an output impedance of the power amplifier, and whose output impedance is conjugate to an impedance on the antenna side. The piezoelectric filter comprises one or more series piezoelectric resonators connected in series between an output side of the power amplifier and the antenna, and two or more parallel piezoelectric resonators connected in parallel between the output side of the power amplifier and the antenna. Among the two or more parallel piezoelectric resonators, on an equivalent circuit, a capacitance of a first parallel piezoelectric resonator closest to the power amplifier side is larger than a capacitance of a second parallel piezoelectric resonator closest to the antenna side.

The present invention also provides a communications apparatus comprising a receiving-side low-noise amplifier, an antenna, and a receiving filter connected between the antenna and the low-noise amplifier. The receiving filter is a piezoelectric filter whose input impedance is conjugate to an impedance of the antenna side, and whose output impedance is conjugate to an input impedance of the low-noise amplifier. The piezoelectric filter comprises one or more series piezoelectric resonators connected in series between the antenna and an input side of the low-noise amplifier, and two or more parallel piezoelectric resonators connected in parallel between the antenna and the input side of the low-noise amplifier. Among the two or more parallel piezoelectric resonators, on an equivalent circuit, a capacitance of a first parallel piezoelectric resonator closest to the antenna side is larger than a capacitance of a second parallel piezoelectric resonator closest to the low-noise amplifier side.

According to the piezoelectric filter of the present invention, since the input impedance and the output impedance can be caused to be different from each other, a matching circuit can be omitted between the amplifier and the filter. As a result, a circuit and a device which require a piezoelectric filter can be miniaturized.

In addition, according to the present invention, no matter what values the pass bandwidth and the stop bandwidth take, if the input impedance and the output impedance are determined, a piezoelectric filter which has satisfactory characteristics in the pass bandwidth and the stop bandwidth can be designed. Therefore, it is possible to provide a piezoelectric filter which has a reduced loss in a desired band.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is an equivalent circuit diagram of a piezoelectric filter 1 according to a first embodiment of the present invention.

FIG. 2 is a cross-sectional view of an exemplary structure of a single piezoelectric resonator of FIG. 1.

FIG. 3A is a graph indicating reflection characteristics (amplitude change versus frequency), where an input terminal 101a has a characteristic impedance of 10 ohms.

FIG. 3B is a Smith chart indicating reflection characteristics, where the input terminal 101a has a characteristic impedance of 10 ohms (normalized with 10 ohms).

FIG. 4A is a graph indicating reflection characteristics (amplitude change versus frequency), where an output terminal 101b has a characteristic impedance of 50 ohms.

FIG. 4B is a Smith chart indicating reflection characteristics, where the output terminal 101b has a characteristic impedance of 50 ohms (normalized with 50 ohms).

FIG. 5 is a graph indicating pass characteristics of a piezoelectric filter.

FIG. 6A is a graph indicating reflection characteristics (amplitude change versus frequency), where the input terminal 101a has a characteristic impedance of 10 ohms.

FIG. 6B is a Smith chart indicating reflection characteristics, where the input terminal 101a has a characteristic impedance of 10 ohms (normalized with 10 ohms).

FIG. 7A is a graph indicating reflection characteristics (amplitude change versus frequency), where the output terminal 101b has a characteristic impedance of 50 ohms.

FIG. 7B is a Smith chart indicating reflection characteristics, where the output terminal 101b has a characteristic impedance of 50 ohms (normalized with 50 ohms).

FIG. 8 is a graph indicating pass characteristics of the piezoelectric filter 1.

FIG. 9A is a graph indicating reflection characteristics (amplitude change versus frequency), where the input terminal 101a has a characteristic impedance of 5 ohms.

FIG. 9B is a Smith chart indicating reflection characteristics, where the input terminal 101a has a characteristic impedance of 5 ohms (normalized with 5 ohms).

FIG. 10A is a graph indicating reflection characteristics (amplitude change versus frequency), where the output terminal 101b has a characteristic impedance of 50 ohms.

FIG. 10B is a Smith chart indicating reflection characteristics, where the output terminal 101b has a characteristic impedance of 50 ohms (normalized with 50 ohms).

FIG. 11 is a graph indicating pass characteristics of the piezoelectric filter 1.

FIG. 12 is an equivalent circuit diagram of a piezoelectric filter 4 according to a fourth embodiment of the present invention.

FIG. 13A is a graph indicating reflection characteristics (amplitude change versus frequency), where an input terminal 1201a has a characteristic impedance of 10 ohms.

FIG. 13B is a Smith chart indicating reflection characteristics, where the input terminal 1201a has a characteristic impedance of 10 ohms (normalized with 10 ohms).

FIG. 14A is a graph indicating reflection characteristics (amplitude change versus frequency), where an output terminal 1201b has a characteristic impedance of 50 ohms.

FIG. 14B is a Smith chart indicating reflection characteristics, where the output terminal 1201b has a characteristic impedance of 50 ohms (normalized with 50 ohms).

FIG. 15 is a graph indicating pass characteristics of a piezoelectric filter 4.

FIG. 16 is an equivalent circuit diagram of a piezoelectric filter 5 according to a fifth embodiment of the present invention.

FIG. 17A is a graph indicating reflection characteristics (amplitude change versus frequency), where an input terminal 1601a has a characteristic impedance of 10 ohms.

FIG. 17B is a Smith chart indicating reflection characteristics, where the input terminal 1601a has a characteristic impedance of 10 ohms (normalized with 10 ohms).

FIG. 18A is a graph indicating reflection characteristics (amplitude change versus frequency), where an output terminal 1601b has a characteristic impedance of 50 ohms.

FIG. 18B is a Smith chart indicating reflection characteristics, where the output terminal 1601b has a characteristic impedance of 50 ohms (normalized with 50 ohms).

FIG. 19 is a graph indicating pass characteristics of a piezoelectric filter 5.

FIG. 20 is an equivalent circuit diagram of a piezoelectric filter 6 according to a sixth embodiment of the present invention.

FIG. 21A is a graph indicating reflection characteristics (amplitude change versus frequency), where an input terminal 2001a has a characteristic impedance of 50 ohms.

FIG. 21B is a Smith chart indicating reflection characteristics, where the input terminal 2001a has a characteristic impedance of 50 ohms (normalized with 50 ohms).

FIG. 22A is a graph indicating reflection characteristics (amplitude change versus frequency), where an output terminal 2001b has a characteristic impedance of 150 ohms.

FIG. 22B is a Smith chart indicating reflection characteristics, where the output terminal 2001b has a characteristic impedance of 150 ohms (normalized with 150 ohms).

FIG. 23 is a graph indicating pass characteristics of a piezoelectric filter 6.

FIG. 24A is a diagram illustrating a structure of a piezoelectric filter which employs a surface acoustic wave resonator and has the equivalent circuit of FIG. 20.

FIG. 24B is a diagram illustrating a structure of the surface acoustic wave resonator.

FIG. 25A is a block diagram illustrating a duplexer 2500 according to an eighth embodiment.

FIG. 25B is a block diagram illustrating a duplexer 2500b according to the eighth embodiment.

FIG. 26 is a block diagram illustrating a structure of a communications apparatus 2600 according to a ninth embodiment.

FIG. 27 is a block diagram illustrating a structure of a communications apparatus 2700 according to a tenth embodiment.

FIG. 28 is a block diagram illustrating conventional peripheral circuitry comprising a piezoelectric filter.

FIG. 29 is a diagram illustrating a conventional filter in which an input-side impedance is different from an output-side impedance.

### DESCRIPTION OF THE REFERENCE CHARACTERS

1, 4, 5, 6 piezoelectric filter
101a input terminal
101b output terminal
102a first series piezoelectric resonator
102b second series piezoelectric resonator
102c third series piezoelectric resonator
103a first parallel piezoelectric resonator
103b second parallel piezoelectric resonator
103c third parallel piezoelectric resonator
104a first inductor
104b second inductor
104c third inductor
201 substrate
202 cavity
203 insulator layer
204 lower electrode
205 piezoelectric material layer
206 upper electrode
207 vibration portion
208 support portion
209 film bulk acoustic resonator
301 marker at 1850 MHz on Smith chart
302 marker at 1910 MHz on Smith chart
303 marker at 1880 MHz on Smith chart
401 marker at 1850 MHz on Smith chart
402 marker at 1910 MHz on Smith chart
403 marker at 1880 MHz on Smith chart
601 marker at 1850 MHz on Smith chart
602 marker at 1910 MHz on Smith chart
603 marker at 1880 MHz on Smith chart
701 marker at 1850 MHz on Smith chart
702 marker at 1910 MHz on Smith chart
703 marker at 1880 MHz on Smith chart
901 marker at 1850 MHz on Smith chart
902 marker at 1910 MHz on Smith chart
903 marker at 1880 MHz on Smith chart
1001 marker at 1850 MHz on Smith chart
1002 marker at 1910 MHz on Smith chart
1003 marker at 1880 MHz on Smith chart
1201a input terminal
1201b output terminal
1202 series piezoelectric resonator
1203a first parallel piezoelectric resonator
1203b second parallel piezoelectric resonator
1204a first inductor
1204b second inductor
1301 marker at 1850 MHz on Smith chart
1302 marker at 1910 MHz on Smith chart
1303 marker at 1880 MHz on Smith chart
1401 marker at 1850 MHz on Smith chart
1402 marker at 1910 MHz on Smith chart
1403 marker at 1880 MHz on Smith chart
1601a input terminal
1601b output terminal
1602a first series piezoelectric resonator
1602b second series piezoelectric resonator
1603 parallel piezoelectric resonator
1604 inductor
1701 marker at 1850 MHz on Smith chart
1702 marker at 1910 MHz on Smith chart
1703 marker at 1880 MHz on Smith chart
1801 marker at 1850 MHz on Smith chart
1802 marker at 1910 MHz on Smith chart
1803 marker at 1880 MHz on Smith chart
2001a input terminal
2001b output terminal
2002a first series piezoelectric resonator
2002b second series piezoelectric resonator
2002c third series piezoelectric resonator
2003a first parallel piezoelectric resonator
2003b second parallel piezoelectric resonator
2004a first inductor
2004b second inductor
2005 bypass piezoelectric resonator
2101 marker at 2110 MHz on Smith chart
2102 marker at 2170 MHz on Smith chart
2103 marker at 2140 MHz on Smith chart
2201 marker at 2110 MHz on Smith chart
2202 marker at 2170 MHz on Smith chart
2203 marker at 2140 MHz on Smith chart
2411 piezoelectric substrate
2412 IDT electrode
2413, 2414 reflector electrode
2500, 2500b duplexer
2501 transmitting terminal
2502 receiving terminal
2503 antenna terminal
2504 transmitting filter
2505 phase shift circuit
2506 receiving filter
2600 communications apparatus
2601 transmitting terminal
2602 base band section
2603 power amplifier
2604 transmitting filter
2605 antenna
2606 receiving filter
2607 LNA
2608 receiving terminal
2700 communications apparatus
2701, 2702 radio block
2703 antenna
2704 switch
2705, 2715 transmitting terminal
2706 base band section
2707, 2716 power amplifier (PA)
2708 duplexer
2709, 2717 transmitting filter
2710 UMTS transmitting/receiving terminal
2711 antenna terminal
2712, 2720 receiving filter
2713, 2721 LNA
2714, 2722 receiving terminal
2718 GSM transmitting terminal
2719 GSM receiving terminal

### BEST MODE FOR CARRYING OUT THE INVENTION

Hereinafter, embodiments of the present invention will be described with reference to the accompanying drawings.

### First Embodiment

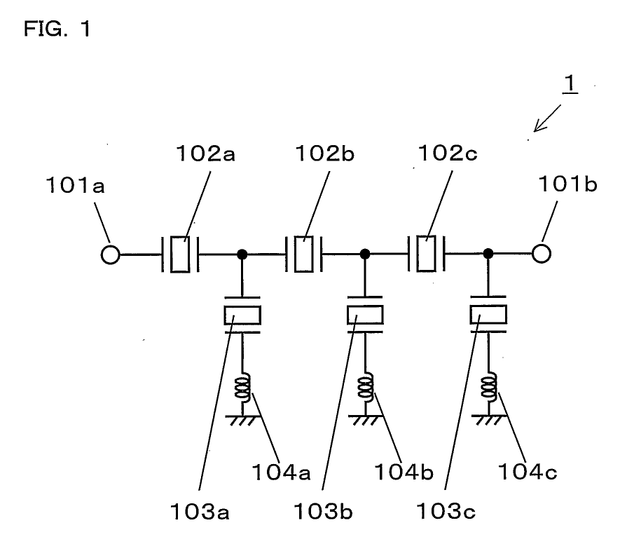

FIG. 1 is an equivalent circuit diagram of a piezoelectric filter 1 according to a first embodiment of the present invention. In FIG. 1, the piezoelectric filter 1 comprises an input terminal 101a, an output terminal 101b, a first series piezoelectric resonator 102a, a second series piezoelectric resonator 102b, a third series piezoelectric resonator 102c, a first parallel piezoelectric resonator 103a, a second parallel piezoelectric resonator 103b, a third parallel piezoelectric resonator 103c, a first inductor 104a, a second inductor 104b, and a third inductor 104c.

The first series piezoelectric resonator 102a, the second series piezoelectric resonator 102b, and the third series piezoelectric resonator 102c are connected in series between the input terminal 101a and the output terminal 101b. An end of the first parallel piezoelectric resonator 103a is provided between the first series piezoelectric resonator 102a and the second series piezoelectric resonator 102b. An end of the second parallel piezoelectric resonator 103b is provided between the second series piezoelectric resonator 102b and the third series piezoelectric resonator 102c. An end of the third parallel piezoelectric resonator 103c is provided between the third series piezoelectric resonator 102c and the output terminal 101b.

The first inductor 104a is provided between a side of the first parallel piezoelectric resonator 103a which is not connected to the first series piezoelectric resonator 102a, and the ground. The second inductor 104b is provided between a side of the second parallel piezoelectric resonator 103b which is not connected to the second series piezoelectric resonator 102b, and the ground. The third inductor 104c is provided between a side of the third parallel piezoelectric resonator 103c which is not connected to the third series piezoelectric resonator 102c, and the ground.

The first series piezoelectric resonator 102a has an capacitance of Cs1 and a resonance frequency of fs1. The second series piezoelectric resonator 102b has a capacitance of Cs2 and a resonance frequency of fs2. The third series piezoelectric resonator 102c has a capacitance of Cs3 and a resonance frequency of fs3. The first parallel piezoelectric resonator 103a has a capacitance of Cp1 and a resonance frequency of fp1. The second parallel piezoelectric resonator 103b has a capacitance of Cp2 and a resonance frequency of fp2. The third parallel piezoelectric resonator 103c has a capacitance of Cp3 and a resonance frequency of fp3. The first inductor 104a has an inductance value of L1. The second inductor 104b has an inductance value of L2. The third inductor 104c has an inductance value of L3.

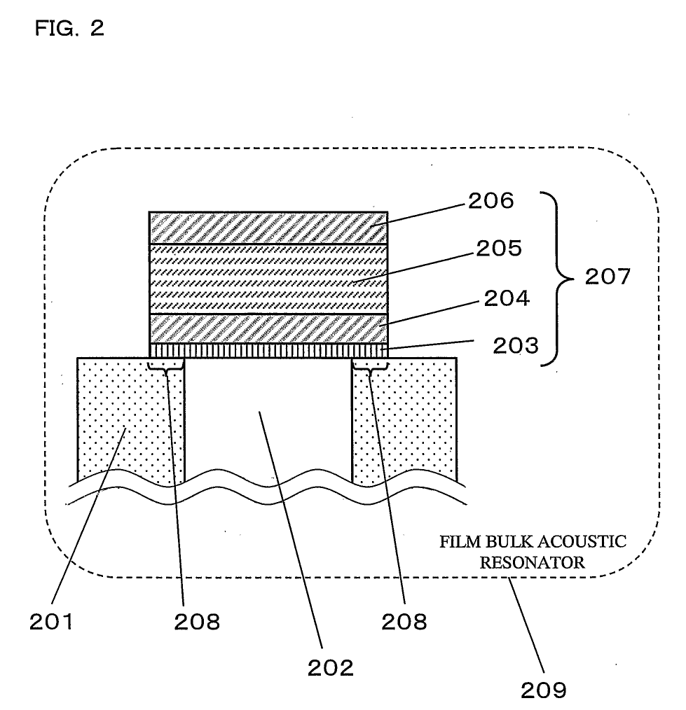

FIG. 2 is a cross-sectional view of an exemplary structure of a single piezoelectric resonator of FIG. 1. In FIG. 2, as an example of the piezoelectric resonator, a film bulk acoustic resonator 209 is illustrated. The film bulk acoustic resonator 209 includes a substrate 201, a cavity 202, an insulator layer 203, a lower electrode 204, a piezoelectric material layer 205, and an upper electrode 206.

The cavity 202 is a penetrating or non-penetrating hole which is formed of a silicon or glass substrate or the like and is provided in the substrate 201. The insulator layer 203 is formed of silicon dioxide (SiO₂), silicon nitride (Si₃N₄), or the like, and is formed covering the cavity 202. The lower electrode 204 is formed of molybdenum (Mo), aluminum (Al), silver (Ag), tungsten (W), platinum (Pt), or the like. The piezoelectric material layer 205 is formed of aluminum nitride (AlN), zinc oxide (ZnO), lithium niobate (LiNbO₃), lithium tantalate (LiTaO₃), potassium niobate (KNbO₃), or the like. The upper electrode 206 is formed of molybdenum (Mo), aluminum (Al), silver (Ag), tungsten (W), platinum (Pt), or the like.

The insulator layer 203, the lower electrode 204, the piezoelectric material layer 205, and the upper electrode 206 are successively formed to construct a vibration portion 207. The vibration portion 207 is fixed to the substrate 201 via a support portion 208 which is in contact with the substrate 201.

In the film bulk acoustic resonator 209, by applying a voltage to the upper electrode 206 and the lower electrode 204, an electric field occurs in the piezoelectric material layer 205. A distortion caused by this is excited as mechanical vibration. This vibration is converted into electric resonance or antiresonance characteristics.

By causing a resonance frequency of a series resonance circuit including the series piezoelectric resonators 102a, 102b, and 102c to be substantially equal to an antiresonance frequency of a parallel resonance circuit including the parallel piezoelectric resonators 103a, 103b, and 103c, the piezoelectric filter 1 of FIG. 1 serves as a bandpass filter having a bandwidth which is determined based on a difference between the antiresonance frequency and the resonance frequency.

The present inventors conducted simulation under the following conditions (first set values) which were set for the capacitance and the resonance frequency of each piezoelectric resonator and the inductance value (equivalent circuit constant) of each inductor.

(First Set Values)

Cs1=2.86 pF, Cs2=0.88 pF, Cs3=0.92 pF, Cp1=14.49 pF, Cp2=5.29 pF, Cp3=2.08 pF, fs1=1979.9 MHz, fs2=1887.5 MHz, fs3=1886.0 MHz, fp1=1866.8 MHz, fp2=1825.7 MHz, fp3=1841.2 MHz, L1=1.49 nH, L2=0.08 nH, and L3=1.47 nH. In each of the series piezoelectric resonators 102a, 102b, and 102c, and in each of the parallel piezoelectric resonators 103a, 103b, and 103c, the difference between the antiresonance frequency and the resonance frequency is 50 MHz.

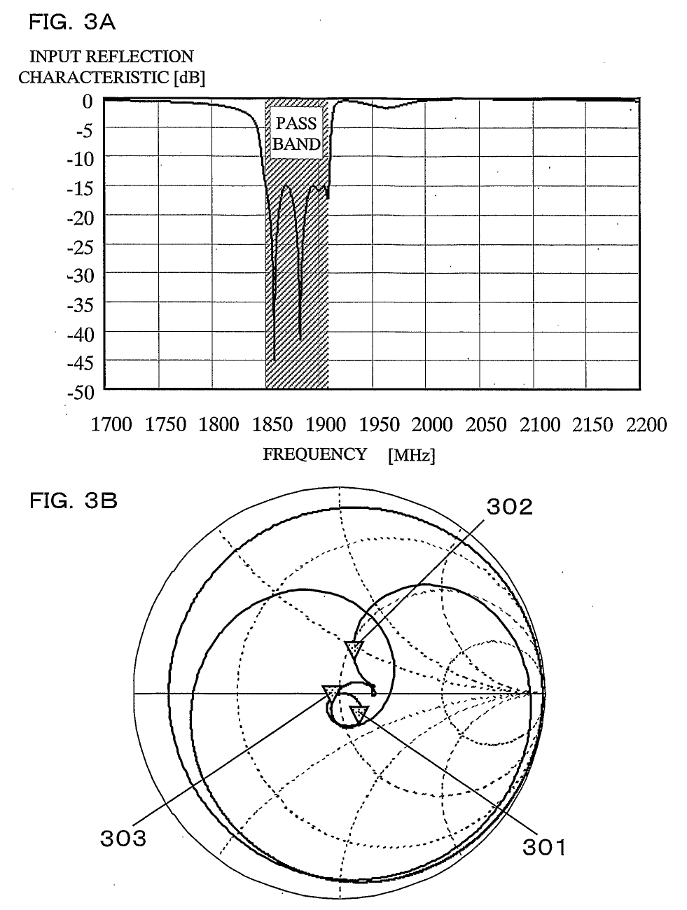

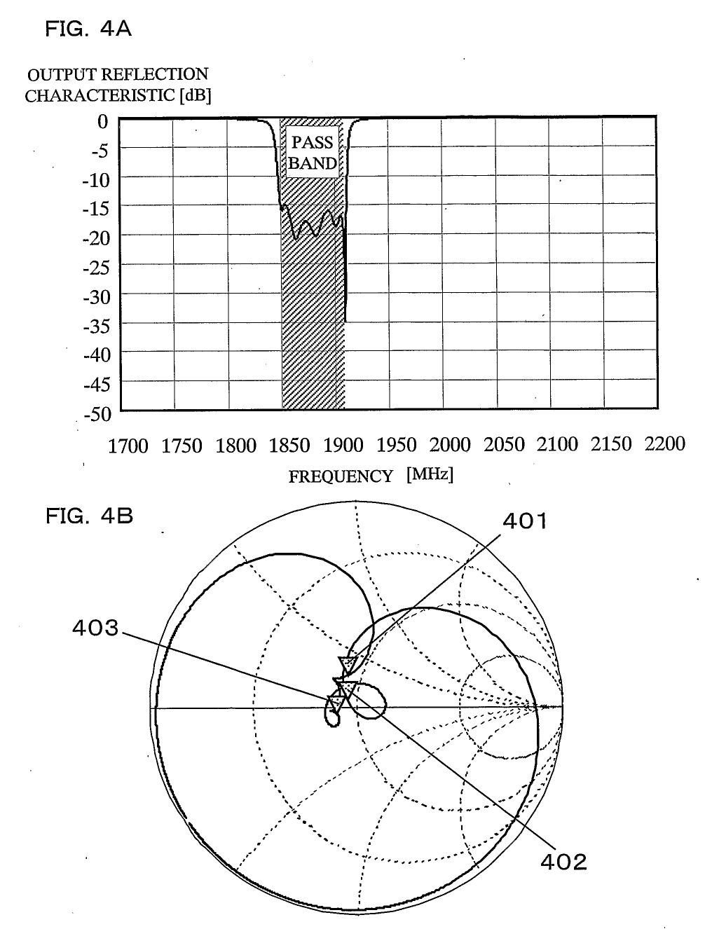

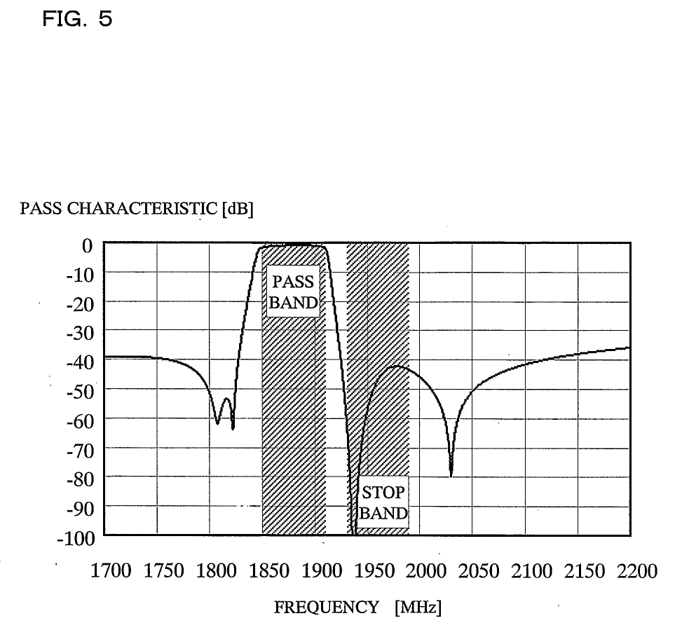

FIG. 3A is a graph indicating reflection characteristics (amplitude change versus frequency), where the input terminal 101a has a characteristic impedance of 10 ohms. FIG. 3B is a Smith chart indicating reflection characteristics, where the input terminal 101a has a characteristic impedance of 10 ohms (normalized with 10 ohms). FIG. 4A is a graph indicating reflection characteristics (amplitude change versus frequency), where the output terminal 101b has a characteristic impedance of 50 ohms. FIG. 4B is a Smith chart indicating reflection characteristics, where the output terminal 101b has a characteristic impedance of 50 ohms (normalized with 50 ohms). FIG. 5 is a graph indicating pass characteristics of the piezoelectric filter 1. In FIGS. 3A, 3B, 4A, 4B, and 5, the above-described first set values are used.

In the Smith chart of FIG. 3B, a marker 301 indicates an impedance of the piezoelectric filter 1 at 1850 MHz. In the Smith chart of FIG. 4B, a marker 401 indicates an impedance of the piezoelectric filter 1 at 1850 MHz. Since the markers 301 and 401 are each located at a center of the Smith chart, it is considered that, at 1850 MHz, the piezoelectric filter 1 has an impedance such that a reflectance is close to zero, when the first set values are used.

In the Smith chart of FIG. 3B, a marker 302 indicates an impedance of the piezoelectric filter 1 at 1910 MHz. In the Smith chart of FIG. 4B, a marker 402 indicates an impedance of the piezoelectric filter 1 at 1910 MHz. Since the markers 302 and 402 are each located close to the center of the Smith chart, it is considered that, at 1910 MHz, the piezoelectric filter 1 has an impedance such that a reflectance is close to zero, when the first set values are used.

In the Smith chart of FIG. 3B, a marker 303 indicates an impedance of the piezoelectric filter 1 at 1880 MHz. In the Smith chart of FIG. 4B, a marker 403 indicates an impedance of the piezoelectric filter 1 at 1880 MHz. Since the markers 303 and 403 are each located close to the center of the Smith chart, it is considered that, at 1880 MHz, the piezoelectric filter 1 has an impedance such that a reflectance is close to zero, when the first set values are used.

As described above, it is found that, in the range of 1850 to 1910 MHz, the piezoelectric filter 1 employing the first set values causes the impedance of the input terminal 101a to substantially match 10 ohms, and the impedance of the output terminal 101b to match 50 ohms. Therefore, as illustrated in FIG. 5, the piezoelectric filter 1 employing the first set values can transmit a signal of 1850 to 1910 MHz with a low loss.

On the other hand, as illustrated in FIG. 5, the piezoelectric filter 1 employing the first set values can significantly attenuate a signal of 1930 to 1990 MHz.

As described above, the piezoelectric filter 1 employing the first set values has filter characteristics such that it transmits a signal with a low loss in a pass band (1850 to 1910 MHz), and attenuates a signal in a stop band (1930 to 1990 MHz).

In the PCS (Personal Communication Services) band used for digital mobile telephone services in the United States, the transmission band is 1850 to 1910 MHz, and the reception band is 1930 to 1990 MHz. Therefore, the piezoelectric filter 1 employing the first set values is useful for the PCS-band digital mobile telephone services.

The above-described first set values are characterized in that the capacitances Cp1, Cp2, and Cp3 of the parallel piezoelectric resonators 103a, 103b, and 103c are successively decreased toward the output terminal 101b in order of distance from the input terminal 101a (smallest first). That is, the relationship Cp1>Cp2>Cp3 is established. Thereby, a piezoelectric filter is achieved which has the input impedance smaller than the output impedance, low loss characteristics in a desired pass band, and high attenuation characteristics in a desired stop band.

In this case, the capacitances Cs1, Cs2, and Cs3 of the series piezoelectric resonators 102a, 102b, and 102c have a relationship Cs1>Cs3>Cs2.

Note that the layer structure of the piezoelectric resonator of FIG. 2 is only for illustrative purposes. Alternatively, a thin piezoelectric material layer or a thin insulator layer may be attached as a passivation film onto an upper side of the upper electrode 206, or an insulating layer may be provided between the piezoelectric material layer 205 and the upper electrode 206 or the lower electrode 204, thereby obtaining a similar effect. In the present invention, the layer structure of the piezoelectric resonator is not limited to these.

Note that the number of stages in the piezoelectric filter is not limited to that which is illustrated in FIG. 1. As long as the capacitances of parallel piezoelectric resonators are successively increased toward the input terminal 101a in order of distance from the output terminal 101b (smallest first), a similar effect is obtained even if the number of series piezoelectric resonators or the number of parallel piezoelectric resonators is different from that which is illustrated in FIG. 1.

### Second Embodiment

A piezoelectric filter according to a second embodiment has an equivalent circuit similar to that of the first embodiment, and therefore, FIG. 1 is referenced again.

The present inventors conducted simulation under the following conditions (second set values) which were set for the capacitance and the resonance frequency of each piezoelectric resonator and the inductance value (equivalent circuit constant) of each inductor.

(Second Set Values)

Cs1=3.06 pF, Cs2=1.12 pF, Cs3=0.97 pF, Cp1=9.95 pF, Cp2=4.86 pF, Cp3=2.35 pF, fs1=1990.0 MHz, fs2=1883.3 MHz, fs3=1884.0 MHz, fp1=1869.7 MHz, fp2=1820.2 MHz, fp3=1837.4 MHz, L1=1.50 nH, L2=0.01 nH, and L3=1.48 nH. In each of the series piezoelectric resonators 102a, 102b, and 102c, and in each of the parallel piezoelectric resonators 103a, 103b, and 103c, the difference between the antiresonance frequency and the resonance frequency is 50 MHz.

As indicated by the second set values, in the piezoelectric filter of the second embodiment, the capacitances Cp1, Cp2, and Cp3 of the parallel piezoelectric resonators 103a, 103b, and 103c are successively decreased toward the output terminal 101b in order of distance from the input terminal 101a (smallest first), i.e., Cp1>Cp2>Cp3. Also, the capacitances Cs1, Cs2, and Cs3 of the series piezoelectric resonators 102a, 102b, and 102c are successively decreased toward the output terminal 101b in order of distance from the input terminal 101a (smallest first), i.e., Cs1>Cs2>Cs3.

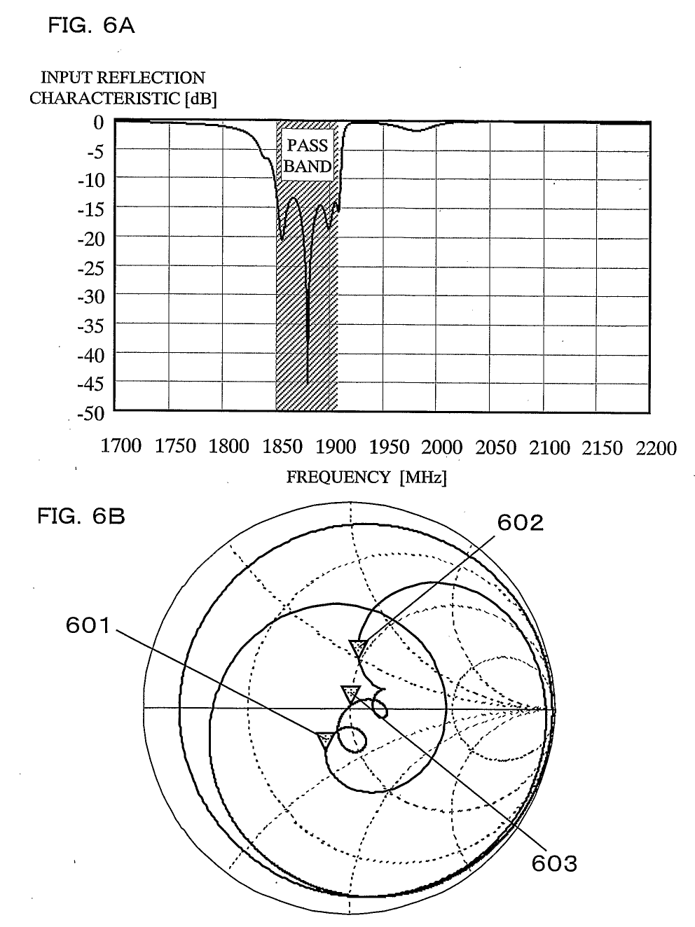

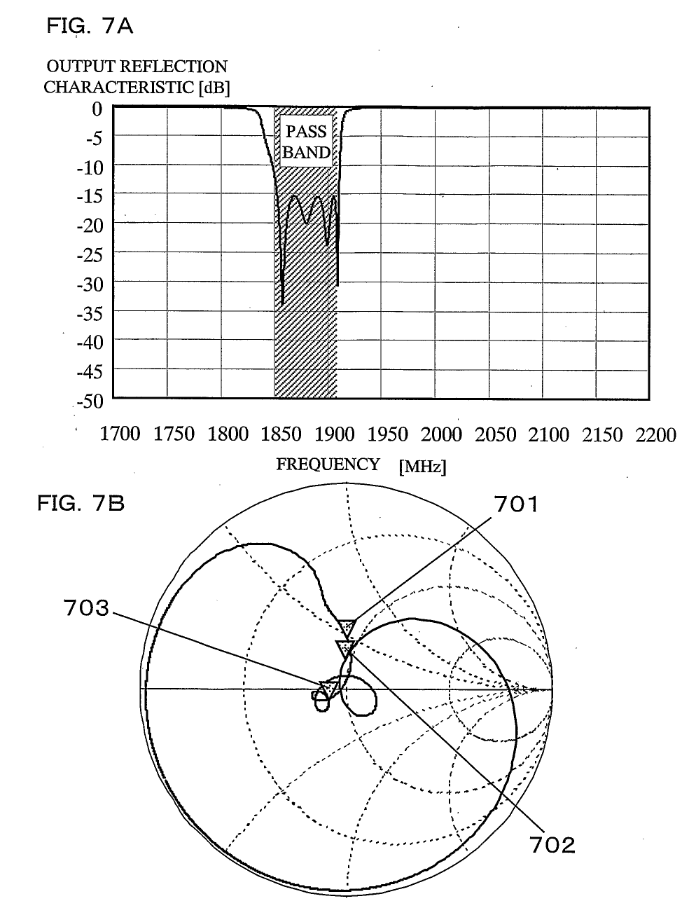

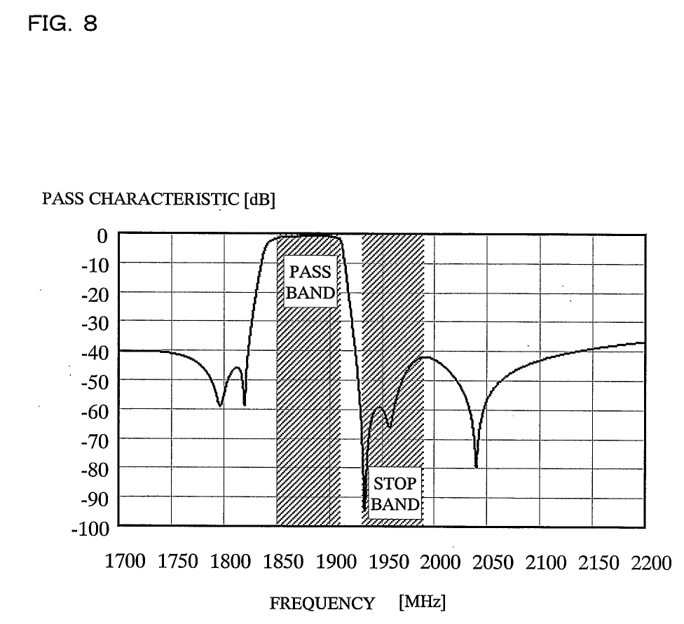

FIG. 6A is a graph indicating reflection characteristics (amplitude change versus frequency), where the input terminal 101a has a characteristic impedance of 10 ohms. FIG. 6B is a Smith chart indicating reflection characteristics, where the input terminal 101a has a characteristic impedance of 10 ohms (normalized with 10 ohms). FIG. 7A is a graph indicating reflection characteristics (amplitude change versus frequency), where the output terminal 101b has a characteristic impedance of 50 ohms. FIG. 7B is a Smith chart indicating reflection characteristics, where the output terminal 101b has a characteristic impedance of 50 ohms (normalized with 50 ohms). FIG. 8 is a graph indicating pass characteristics of the piezoelectric filter 1. In FIGS. 6A, 6B, 7A, 7B, and 8, the above-described second set values are used.

In the Smith charts of FIGS. 6B and 7B, markers 601 and 701 each indicate an impedance at 1850 MHz (the lower end of the pass band of the transmitting side of PCS), markers 602 and 702 each indicate an impedance at 1910 MHz (the higher end of the pass band of the transmitting side of PCS), and markers 603 and 703 each indicate an impedance at 1880 MHz (the center of the pass band of the transmitting side of PCS).

As illustrated in FIGS. 6A, 6B, 7A, 7B, and 8, the capacitances of the series piezoelectric resonators 102a, 102b, and 102c are successively increased toward the input terminal 101a in order of distance from the output terminal 101b (smallest first), and the capacitances of the parallel piezoelectric resonators 103a, 103b, and 103c are increased toward the input terminal 101a in order of distance from the output terminal 101b (smallest first). Thereby, a PCS-band transmitting piezoelectric filter is achieved in which, in the pass band (1850 to 1910 MHz) of PCS, an impedance is substantially matched to 10 ohms at the input terminal 101a, an impedance is substantially matched to 50 ohms at the output terminal 101b, and a signal is transmitted with a low loss; and in the reception band (1930 to 1990 MHz) which is a stop band, a signal can be significantly attenuated.

### Third Embodiment

A piezoelectric filter according to a third embodiment has an equivalent circuit similar to that of the first embodiment, and therefore, FIG. 1 is referenced again.

The present inventors conducted simulation under the following conditions which were set for the capacitance and the resonance frequency of each piezoelectric resonator and the inductance value (equivalent circuit constant) of each inductor (third set values).

(Third Set Values)

Cs1=3.34 pF, Cs2=0.72 pF, Cs3=0.81 pF, Cp1=18.08 pF, Cp2=4.22 pF, Cp3=2.20 pF, fs1=1979.0 MHz, fs2=1887.2 MHz, fs3=1884.6 MHz, fp1=1892.8 MHz, fp2=1824.0 MHz, fp3=1835.5 MHz, L1=1.43 nH, L2=0.01 nH, and L3=1.50 nH. In each of the series piezoelectric resonators 102a, 102b, and 102c, and in each of the parallel piezoelectric resonators 103a, 103b, and 103c, the difference between the antiresonance frequency and the resonance frequency is 50 MHz.

As indicated with the third set values, in the piezoelectric filter of the third embodiment, the capacitances Cp1, Cp2, and Cp3 of the parallel piezoelectric resonators 103a, 103b, and 103c are successively decreased toward the output terminal 101b in order of distance from the input terminal 101a (smallest first), i.e., Cp1>Cp2>Cp3.

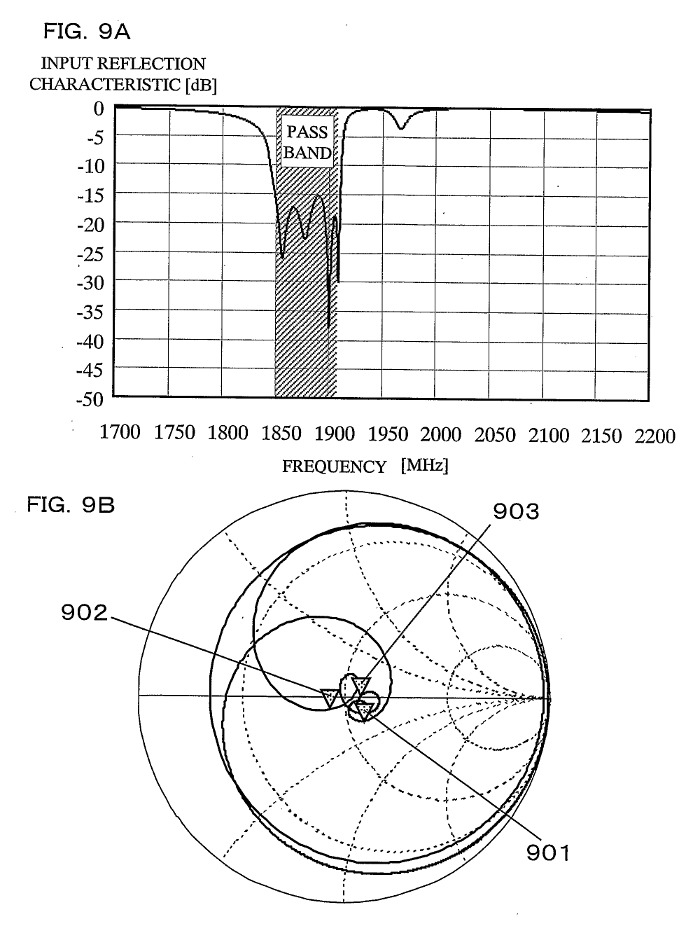

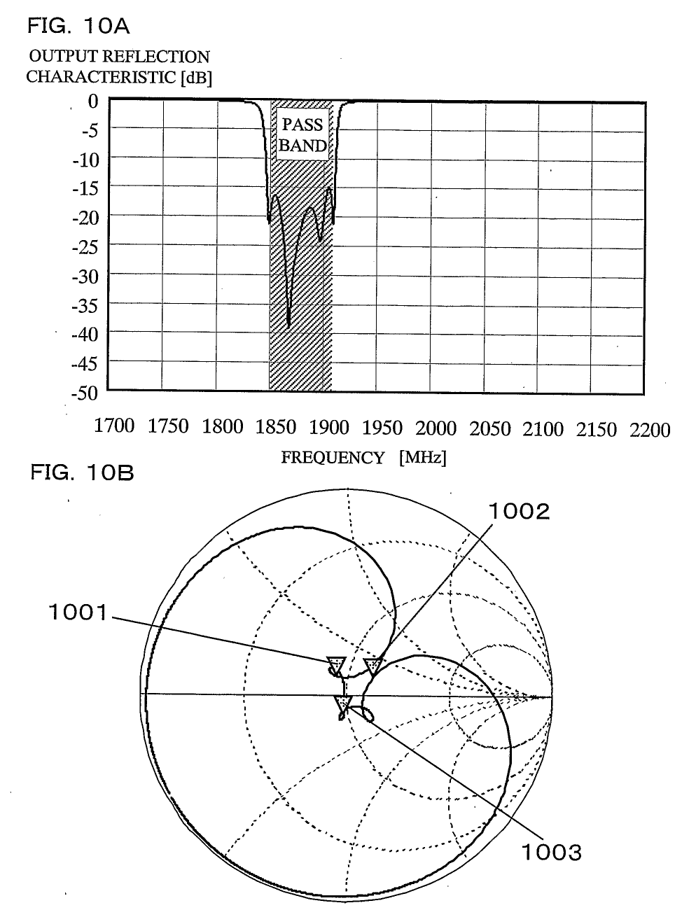

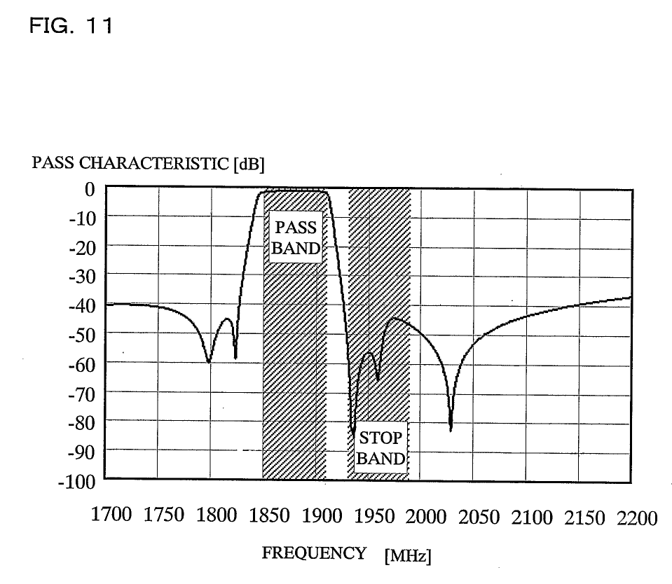

FIG. 9A is a graph indicating reflection characteristics (amplitude change versus frequency), where the input terminal 101a has a characteristic impedance of 5 ohms. FIG. 9B is a Smith chart indicating reflection characteristics, where the input terminal 101a has a characteristic impedance of 5 ohms (normalized with 5 ohms). FIG. 10A is a graph indicating reflection characteristics (amplitude change versus frequency), where the output terminal 101b has a characteristic impedance of 50 ohms. FIG. 10B is a Smith chart indicating reflection characteristics, where the output terminal 101b has a characteristic impedance of 50 ohms (normalized with 50 ohms). FIG. 11 is a graph indicating pass characteristics of the piezoelectric filter 1. In FIGS. 9A, 9B, 10A, 10B, and 11, the above-described third set values are used.

In the Smith charts of FIGS. 9B and 10B, markers 901 and 1001 each indicate an impedance at 1850 MHz (the lower end of the pass band of the transmitting side of PCS), markers 902 and 1002 each indicate an impedance at 1910 MHz (the higher end of the pass band of the transmitting side of PCS), and markers 903 and 1003 each indicate an impedance at 1880 MHz (the center of the pass band of the transmitting side of PCS).

As illustrated in FIGS. 9A, 9B, 10A, 10B, and 11, the capacitances of the parallel piezoelectric resonators 103a, 103b, and 103c are increased toward the input terminal 101a in order of distance from the output terminal 101b (smallest first). Thereby, a PCS-band transmitting piezoelectric filter is achieved in which, in the pass band (1850 to 1910 MHz) of PCS, an impedance is substantially matched to 5 ohms at the input terminal 101a, an impedance is substantially matched to 50 ohms at the output terminal 101b, and a signal is transmitted with a low loss; and in the reception band (1930 to 1990 MHz) which is a stop band, a signal can be significantly attenuated.

Note that the piezoelectric filter of the present invention is not limited to a specific impedance, such as 5 ohms, 10 ohms, or the like. The piezoelectric filter of the present invention can be achieved by setting a value (piezoelectric filter constant) of each element in the piezoelectric filter to an appropriate value, even if the input impedance is any value in the range of 5 ohms to 50 ohms.

The piezoelectric filter of the present invention is considered to be connected to an output side of a power amplifier. Therefore, the input impedance of the piezoelectric filter may be determined, depending on an output impedance of the power amplifier.

In other words, in order to produce the piezoelectric filter of the present invention, the piezoelectric filter may be designed to have an input impedance conjugate to the output impedance of the power amplifier. An exemplary procedure of the design will be described as follows. After the input impedance of the piezoelectric filter is determined, the equivalent circuit constant is set to be an appropriate value, and a Smith chart normalized with the input impedance and a Smith chart normalized with the output impedance are produced. In these Smith charts, if a reflectance is close to zero within a desired pass band, and a reflectance is large within a desired stop band, the set equivalent circuit constant is considered to be appropriate. If a reflectance is not close to zero within the pass band, and a reflectance is not large within the stop band, the set equivalent circuit constant is not considered to be appropriate. Therefore, a new equivalent circuit constant is set to produce a Smith chart in a similar manner and observe a reflectance. Thereby, if an equivalent circuit constant which allows an appropriate reflectance to be obtained is found, a piezoelectric filter employing the equivalent circuit constant has desired input and output impedances, and low loss and high attenuation characteristics within the desired pass and stop bands.

What the first to third embodiments have in common with each other is that the capacitances Cp1, Cp2, and Cp3 of the parallel piezoelectric resonators 103a, 103b, and 103c are successively decreased toward the output terminal 101b in order of distance from the input terminal 101a (smallest first), i.e., Cp1>Cp2>Cp3. Therefore, when the piezoelectric filter of the present invention is designed, the piezoelectric filter constant is selected so that the capacitances of the parallel piezoelectric resonators in the piezoelectric filter are successively decreased toward the output terminal in order of distance from the input terminal (smallest first), on an equivalent circuit thereof. Thereby, a piezoelectric filter is obtained which has desired input and output impedances, and low loss and high attenuation characteristics within desired pass and stop bands.

In the first and third embodiments, the relationship Cs1>Cs3>Cs2 is established. On the other hand, in the second embodiment, the relationship Cs1>Cs2>Cs3 is established. Therefore, if the capacitances of the parallel piezoelectric resonators are decreased toward the output terminal side in order of distance from the input terminal side (smallest first), the effect of the present invention is obtained no matter what capacitances of the series piezoelectric resonators are set. Note that, preferably, the capacitances of the series piezoelectric resonators in the first to third embodiments may be such that the capacitance on the input terminal side is larger than the capacitance on the output terminal side, on an equivalent circuit, i.e., Cs1>Cs3. In addition, the series piezoelectric resonators may have capacitances which are decreased toward the output terminal side in order of distance from the input terminal side (smallest first), on the equivalent circuit.

### Fourth Embodiment

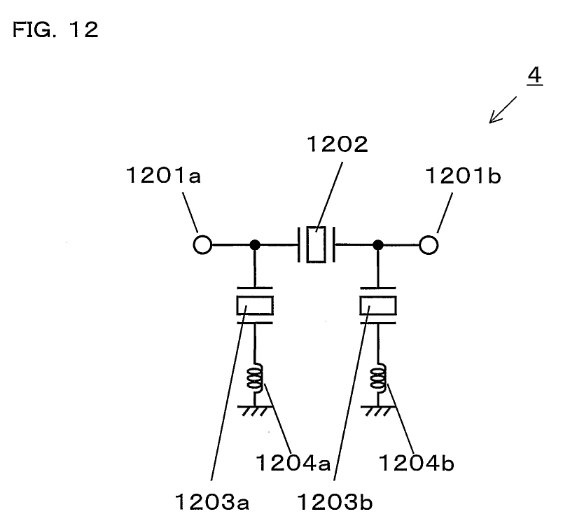

FIG. 12 is an equivalent circuit diagram of a piezoelectric filter 4 according to a fourth embodiment of the present invention. The piezoelectric filter 4 of the fourth embodiment is a three-stage n-type piezoelectric filter.

In FIG. 12, the piezoelectric filter 4 comprises an input terminal 1201a, an output terminal 1201b, a series piezoelectric resonator 1202, a first parallel piezoelectric resonator 1203a, a second parallel piezoelectric resonator 1203b, a first inductor 1204a, and a second inductor 1204b.

The series piezoelectric resonator 1202 is connected between the input terminal 1201a and the output terminal 1201b. One end of the first parallel piezoelectric resonator 1203a is connected between the input terminal 1201a and the series piezoelectric resonator 1202. The other end of the first parallel piezoelectric resonator 1203a is grounded via the first inductor 1204a. One of the second parallel piezoelectric resonator 1203b is connected between the series piezoelectric resonator 1202 and the output terminal 1201b. The other end of the second parallel piezoelectric resonator 1203b is grounded via the second inductor 1204b.

The present inventors conducted simulation under the following conditions which were set for the capacitance and the resonance frequency of each piezoelectric resonator and the inductance value (equivalent circuit constant) of each inductor (fourth set values).

(Fourth Set Values)

The series piezoelectric resonator 1202 has a capacitance Cs of 2.36 pF. The first parallel piezoelectric resonator 1203a has a capacitance Cp1 of 14.93 pF. The second parallel piezoelectric resonator 1203b has a capacitance Cp2 of 26.66 pF. The series piezoelectric resonator 1202 has a resonance frequency fs of 1944.6 MHz. The first parallel piezoelectric resonator 1203a has a resonance frequency fp1 of 1848.5 MHz. The second parallel piezoelectric resonator 1203b has a resonance frequency fp2 of 1883.6 MHz. The first inductor 1204a has an inductance value L1 of 1.19 nH. The second inductor 1204b has an inductance value L2 of 1.76 nH. In each of the series piezoelectric resonator 1202, and the parallel piezoelectric resonators 1203a and 1203b, the difference between the antiresonance frequency and the resonance frequency is 50 MHz.

As indicated with the fourth set values, in the piezoelectric filter 4 of the fourth embodiment, the capacitance Cp1 of the first parallel piezoelectric resonator 1203a is larger than the capacitance Cp2 of the second parallel piezoelectric resonator 1203b, i.e., Cp1>Cp2.

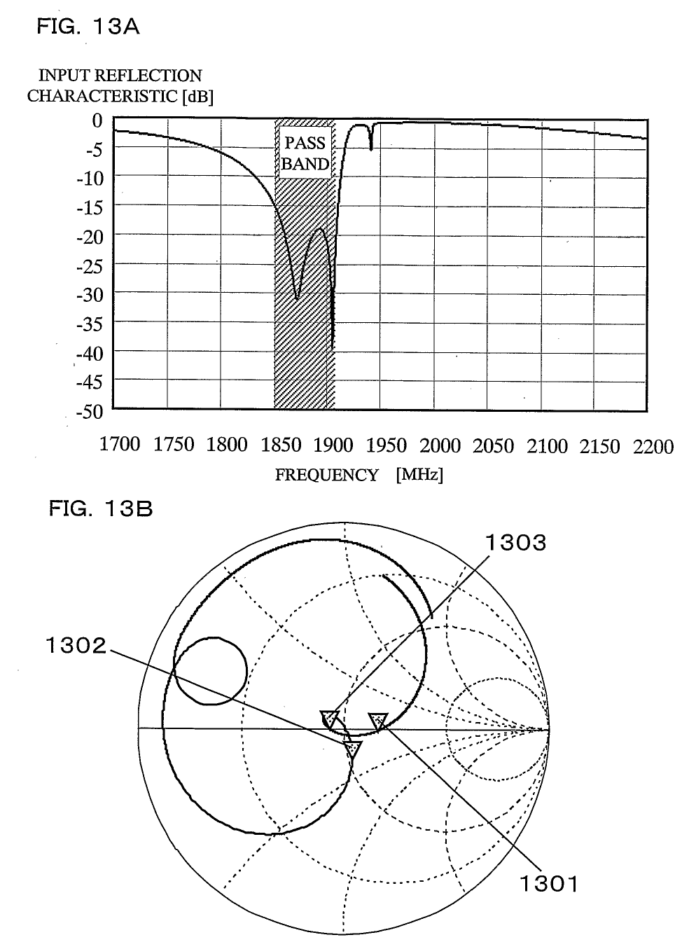

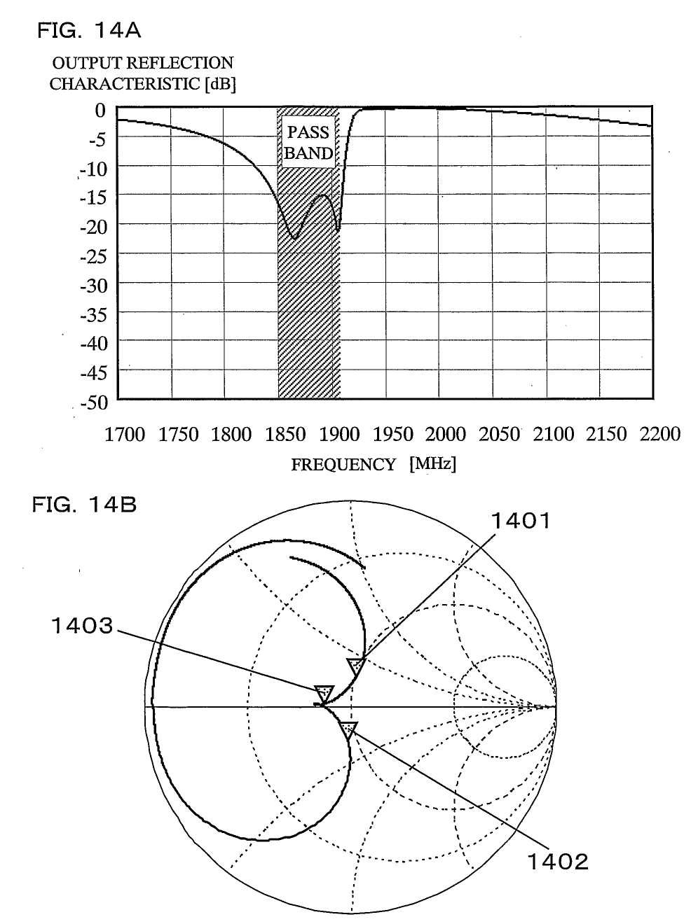

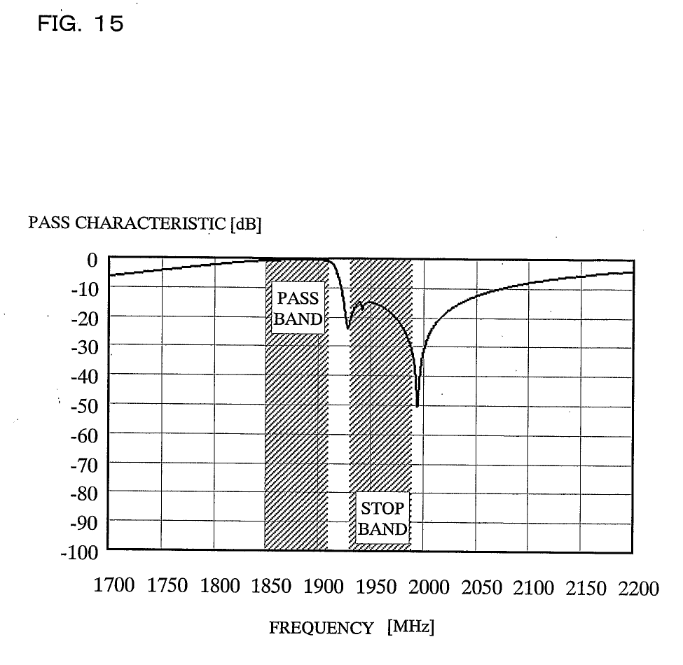

FIG. 13A is a graph indicating reflection characteristics (amplitude change versus frequency), where the input terminal 1201a has a characteristic impedance of 10 ohms. FIG. 13B is a Smith chart indicating reflection characteristics, where the input terminal 1201a has a characteristic impedance of 10 ohms (normalized with 10 ohms). FIG. 14A is a graph indicating reflection characteristics (amplitude change versus frequency), where the output terminal 1201b has a characteristic impedance of 50 ohms. FIG. 14B is a Smith chart indicating reflection characteristics, where the output terminal 1201b has a characteristic impedance of 50 ohms (normalized with 50 ohms). FIG. 15 is a graph indicating pass characteristics of the piezoelectric filter 4. In FIGS. 13A, 13B, 14A, 14B, and 15, the above-described fourth set values are used.

In the Smith charts of FIGS. 13B and 14B, markers 1301 and 1401 each indicate an impedance at 1850 MHz (the lower end of the pass band of the transmitting side of PCS), markers 1302 and 1402 each indicate an impedance at 1910 MHz (the higher end of the pass band of the transmitting side of PCS), and markers 1303 and 1403 each indicate an impedance at 1880 MHz (the center of the pass band of the transmitting side of PCS).

As illustrated in FIGS. 13A, 13B, 14A, 14B, and 15, the capacitance Cp1 of the first parallel piezoelectric resonator 1203a is larger than the capacitance Cp2 of the second parallel piezoelectric resonator 1203b. Thereby, within the pass band (1850 to 1910 MHz), filter characteristics are achieved such that an impedance is substantially matched to 10 ohms at the input terminal 1201a, and an impedance is substantially matched to 50 ohms at the output terminal 1201b, and a signal is transmitted with a low loss. Note that, as illustrated in FIG. 15, since the number of piezoelectric resonators in the piezoelectric filter is as small as three, the amount of attenuation within the stop band (1930 to 1990 MHz) is not large. Nevertheless, a piezoelectric filter in which the input and output impedances are different from each other can be achieved.

According to the fourth embodiment, it is found that, at least if the capacitance of a parallel piezoelectric resonator closest to the input terminal side is larger than the capacitance of a parallel piezoelectric resonator closest to the output terminal side, a piezoelectric filter capable of transmitting a signal with a low loss is provided. Therefore, in a piezoelectric filter which has three or more parallel piezoelectric resonators, the capacitances of parallel piezoelectric resonator(s) except for those at both of the ends, may be either smaller or larger than the capacitance of the parallel piezoelectric resonator on the input terminal side. In other words, in an example as illustrated in FIG. 1, either Cp1>Cp3>Cp2 or Cp2>Cp1>Cp3 may be established.

Note that the number of piezoelectric filters is not limited to that which is illustrated in FIG. 12. The number of filters is determined based on the desired filter characteristics and stop band attenuated amount. A similar effect is obtained when three or more piezoelectric filters are used.

### Fifth Embodiment

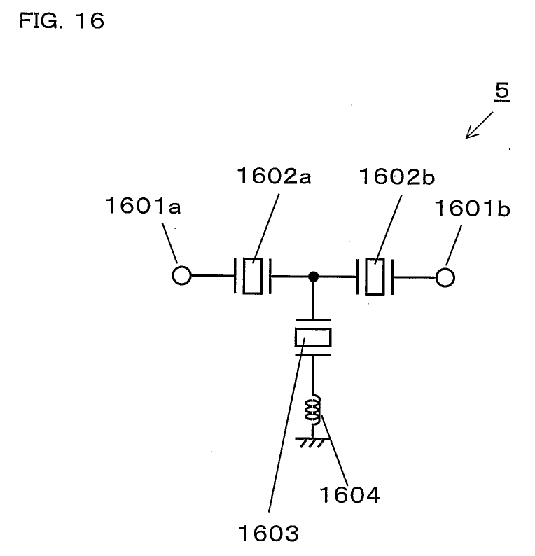

FIG. 16 is an equivalent circuit diagram of a piezoelectric filter 5 according to a fifth embodiment of the present invention. The piezoelectric filter 5 of the fifth embodiment is a three-stage T-type piezoelectric filter. In FIG. 16, the piezoelectric filter 5 comprises an input terminal 1601a, an output terminal 1601b, a first series piezoelectric resonator 1602a, a second series piezoelectric resonator 1602b, a parallel piezoelectric resonator 1603, and an inductor 1604.

The first series piezoelectric resonator 1602a and the second series piezoelectric resonator 1602b are connected in series between the input terminal 1601a and the output terminal 1601b. One end of the parallel piezoelectric resonator 1603 is connected between the first series piezoelectric resonator 1602a and the second series piezoelectric resonator 1602b. The other end of the parallel piezoelectric resonator 1603 is grounded via the inductor 1604.

The present inventors conducted simulation under the following conditions which were set for the capacitance and the resonance frequency of each piezoelectric resonator and the inductance value (equivalent circuit constant) of each inductor (fifth set values).

(Fifth Set Values)

The first series piezoelectric resonator 1602a has a capacitance Cs1 of 2.45 pF. The second series piezoelectric resonator 1602b has a capacitance Cs2 of 1.75 pF. The parallel piezoelectric resonator 1603 has a capacitance Cp of 6.12 pF. The first series piezoelectric resonator 1602a has a resonance frequency fs1 of 1987.7 MHz. The second series piezoelectric resonator 1602b has a resonance frequency fs2 of 1887.4 MHz. The parallel piezoelectric resonator 1603 has a resonance frequency fp of 1895.6 MHz. The inductor 1604 has an inductance value L of 2.61 nH. In each of the series piezoelectric resonators 1602a and 1602b and the parallel piezoelectric resonator 1603, the difference between the antiresonance frequency and the resonance frequency is 50 MHz.

As indicated with the fifth set values, in the piezoelectric filter 5 of the fifth embodiment, the capacitance Cs1 of the first series piezoelectric resonator 1602a is larger than the capacitance Cs2 of the second series piezoelectric resonator 1602b, i.e., Cs1>Cs2.

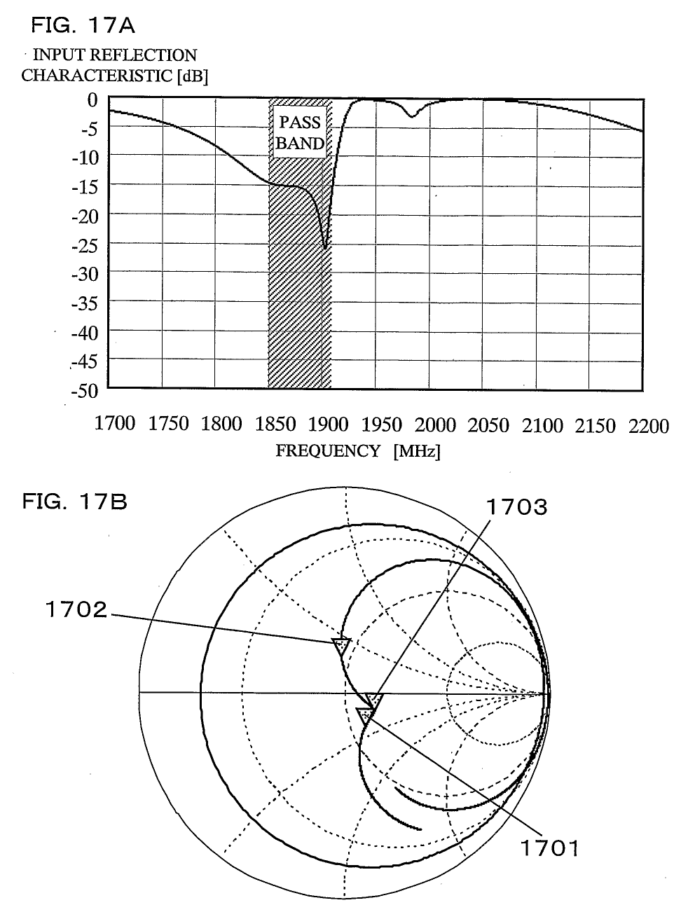

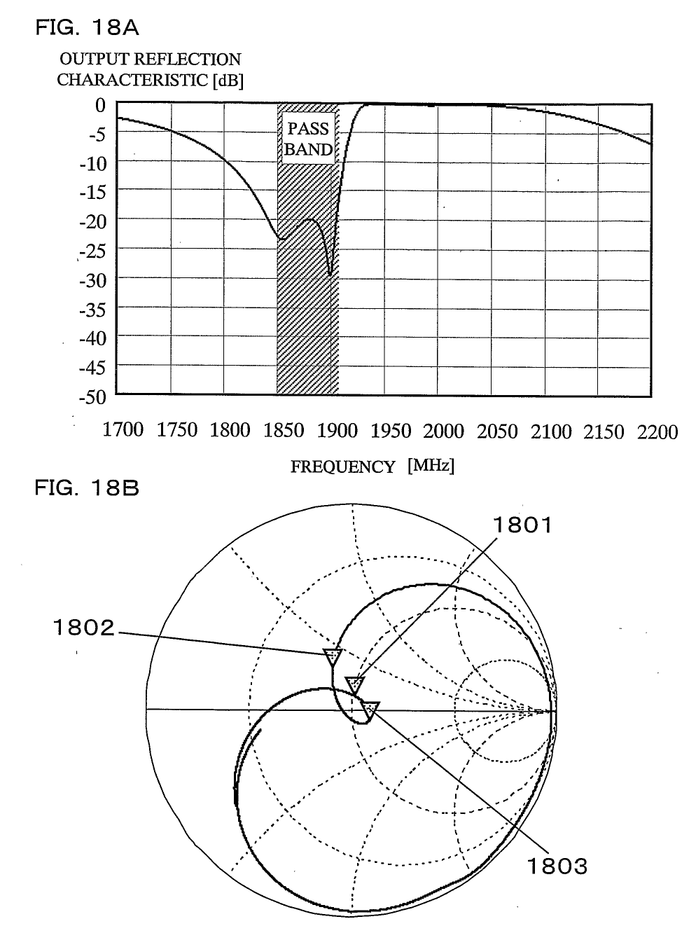

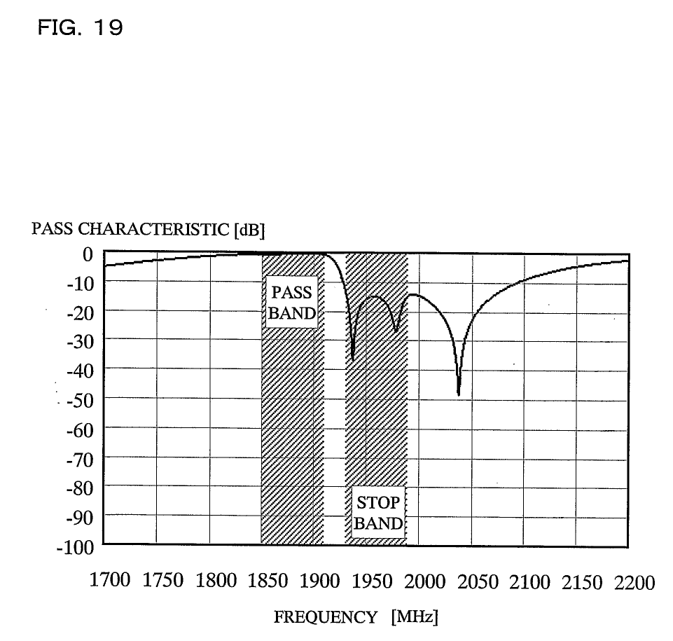

FIG. 17A is a graph indicating reflection characteristics (amplitude change versus frequency), where the input terminal 1601a has a characteristic impedance of 10 ohms. FIG. 17B is a Smith chart indicating reflection characteristics, where the input terminal 1601a has a characteristic impedance of 10 ohms (normalized with 10 ohms). FIG. 18A is a graph indicating reflection characteristics (amplitude change versus frequency), where the output terminal 1601b has a characteristic impedance of 50 ohms. FIG. 18B is a Smith chart indicating reflection characteristics, where the output terminal 1601b has a characteristic impedance of 50 ohms (normalized with 50 ohms). FIG. 19 is a graph indicating pass characteristics of the piezoelectric filter 5. In FIGS. 17A, 17B, 18A, 18B, and 19, the above-described fifth set values are used.

In the Smith charts of FIGS. 17B and 18B, markers 1701 and 1801 each indicate an impedance at 1850 MHz (the lower end of the pass band of the transmitting side of PCS), markers 1702 and 1802 each indicate an impedance at 1910 MHz (the higher end of the pass band of the transmitting side of PCS), and markers 1703 and 1803 each indicate an impedance at 1880 MHz (the center of the pass band of the transmitting side of PCS).

As illustrated in FIGS. 17A, 17B, 18A, 18B, and 19, the capacitance Cs1 of the first series piezoelectric resonator 1602a is larger than the capacitance Cs2 of the second series piezoelectric resonator 1602b. Thereby, within the pass band (1850 to 1910 MHz), filter characteristics are achieved such that an impedance is substantially matched to 10 ohms at the input terminal 1601a, and an impedance is substantially matched to 50 ohms at the output terminal 1601b, and a signal is transmitted with a low loss. Note that, since the number of piezoelectric resonators in the piezoelectric filter is as small as three, the amount of attenuation within the stop band (1930 to 1990 MHz) is not large. Nevertheless, a piezoelectric filter in which the input and output impedances are different from each other can be achieved.

According to the fifth embodiment, it is found that, at least if the capacitance of a series piezoelectric resonator closest to the input terminal side is larger than the capacitance of a series piezoelectric resonator closest to the output terminal side, a piezoelectric filter capable of transmitting a signal with a low loss is provided. Therefore, in a piezoelectric filter which has three or more series piezoelectric resonators, the capacitances of series piezoelectric resonator(s) except for those at both of the ends, may be either smaller or larger than the capacitance of the series piezoelectric resonator on the input terminal side. In other words, in an example as illustrated in FIG. 1, either Cs1>Cs3>Cs2 or Cs2>Cs1>Cs3 may be established.

Note that the number of piezoelectric filters is not limited to that which is illustrated in FIG. 16. The number of filters is determined based on the desired filter characteristics and stop band attenuated amount. A similar effect is obtained when three or more piezoelectric filters are used.

### Sixth Embodiment

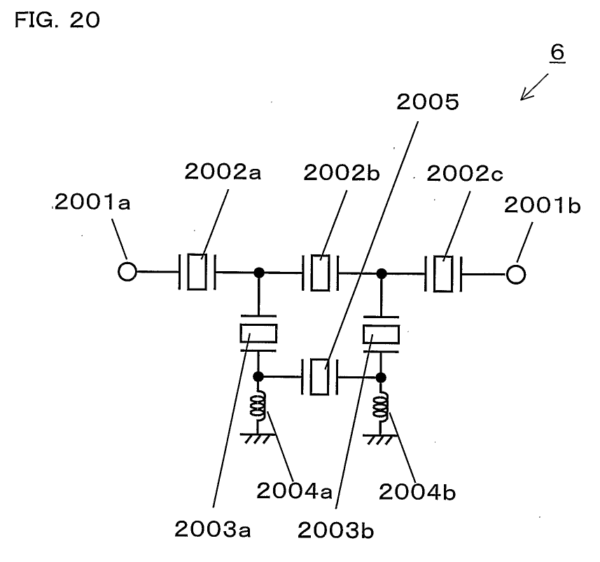

FIG. 20 is an equivalent circuit diagram of a piezoelectric filter 6 according to a sixth embodiment of the present invention. In FIG. 20, the piezoelectric filter 6 comprises an input terminal 2001a, an output terminal 2001b, a first series piezoelectric resonator 2002a, a second series piezoelectric resonator 2002a, a third series piezoelectric resonator 2002c, a first parallel piezoelectric resonator 2003a, a second parallel piezoelectric resonator 2003b, a first inductor 2004a, a second inductor 2004b, and a bypass piezoelectric resonator 2005.

The first series piezoelectric resonator 2002a, the second series piezoelectric resonator 2002a, and the third series piezoelectric resonator 2002c are successively connected in series between the input terminal 2001a and the output terminal 2001b. One end of the first parallel piezoelectric resonator 2003a is provided between the first series piezoelectric resonator 2002a and the second series piezoelectric resonator 2002a. The other end of the first parallel piezoelectric resonator 2003a is grounded via the first inductor 2004a. One end of the second parallel piezoelectric resonator 2003b is provided between the second series piezoelectric resonator 2002a and the third series piezoelectric resonator 2002c. The other end of the second parallel piezoelectric resonator 2003b is grounded via the second inductor 2004b. The bypass piezoelectric resonator 2005 is connected between a connection point of the first parallel piezoelectric resonator 2003a and the first inductor 2004a and a connection point of the second parallel piezoelectric resonator 2003b and the second inductor 2004b.

The present inventors conducted simulation under the following conditions which were set for the capacitance and the resonance frequency of each piezoelectric resonator and the inductance value (equivalent circuit constant) of each inductor (sixth set values).

(Sixth Set Values)

The first series piezoelectric resonator 2002a has a capacitance Cs1 of 1.91 pF. The second series piezoelectric resonator 2002a has a capacitance Cs2 of 0.51 pF. The third series piezoelectric resonator 2002c has a capacitance Cs3 of 1.00 pF. The first parallel piezoelectric resonator 2003a has a capacitance Cp1 of 1.89 pF. The second parallel piezoelectric resonator 2003b has a capacitance Cp2 of 1.50 pF. The bypass piezoelectric resonator 2005 has a capacitance Cb of 1.18 pF. The first series piezoelectric resonator 2002a has a resonance frequency fs1 of 2137.2 MHz. The second series piezoelectric resonator 2002a has a resonance frequency fs2 of 2203.1 MHz. The third series piezoelectric resonator 2002c has a resonance frequency fs3 of 2144.9 MHz. The first parallel piezoelectric resonator 2003a has a resonance frequency fp1 of 2090.1 MHz. The second parallel piezoelectric resonator 2003b has a resonance frequency fp2 of 2121.6 MHz. The bypass piezoelectric resonator 2005 has a resonance frequency fb of 1950 MHz. The first inductor 2004a has an inductance value L1 of 0.63 nH. The second inductor 2004b has an inductance value L2 of 2.97 nH. In each of the series piezoelectric resonators 2002a, 2002b, and 2002c, the parallel piezoelectric resonators 2003a and 2003b, and the bypass piezoelectric resonator 2005, the difference between the antiresonance frequency and the resonance frequency is 50 MHz. The piezoelectric filter 6 is a receiving filter used in the UMTS (Universal Mobile Telecommunications System) which is a specification for third-generation mobile telephone services.

As indicated with the sixth set values, in the piezoelectric filter 6 of the sixth embodiment, the capacitance Cp1 of the first parallel piezoelectric resonator 2003a is larger than the capacitance Cp2 of the second parallel piezoelectric resonator 2003b, i.e., Cp1>Cp2. In addition, among the capacitances Cs1, Cs2, and Cs3 of the series piezoelectric resonators 2002a, 2002b, and 2002c, the capacitance Cs1 close to the input terminal 2001a is larger than the capacitance Cs2 close to the output terminal 2001b.

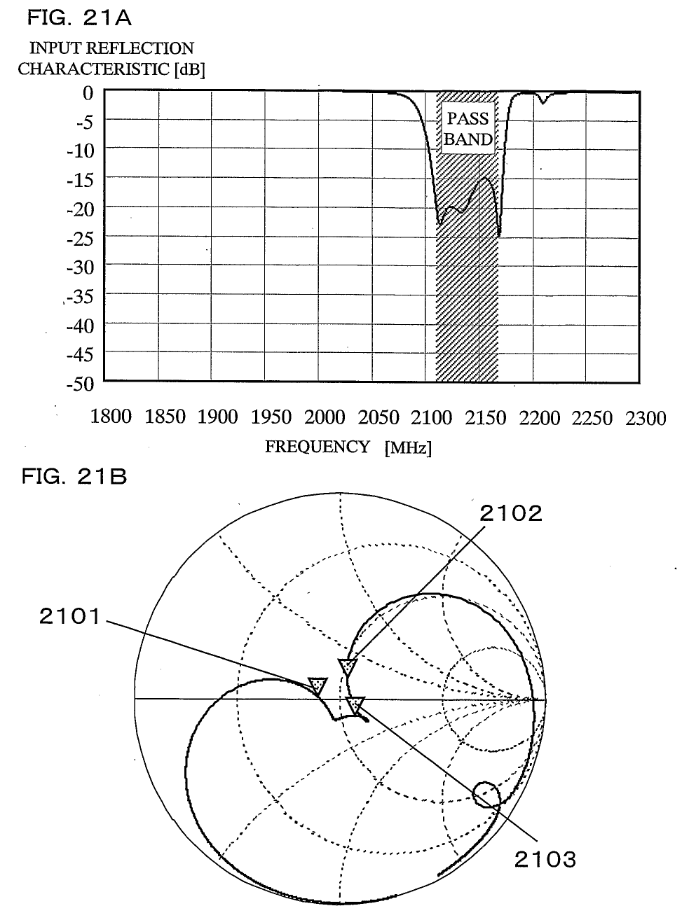

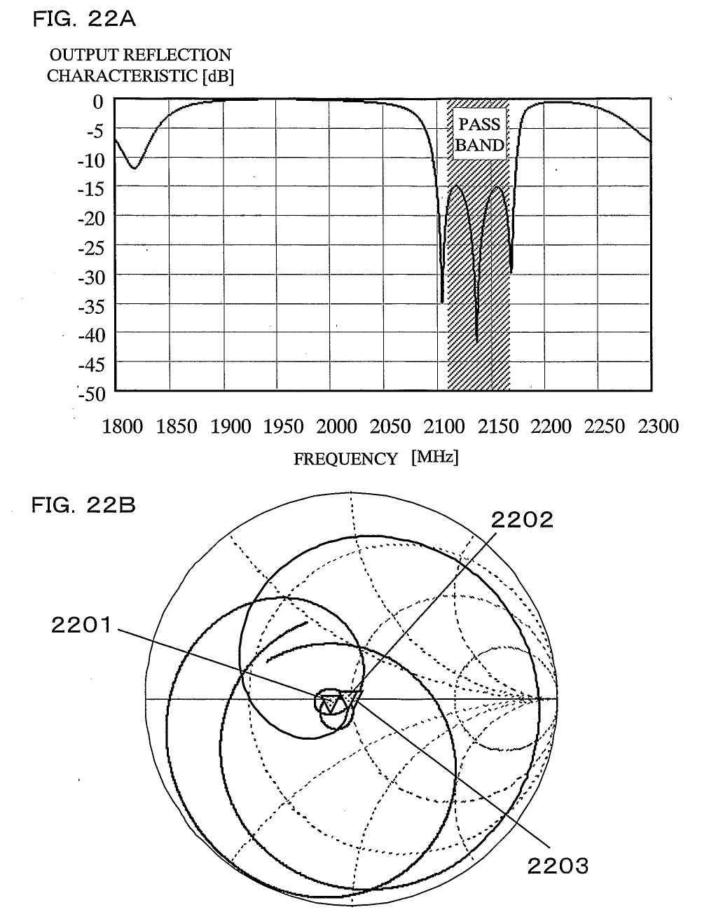

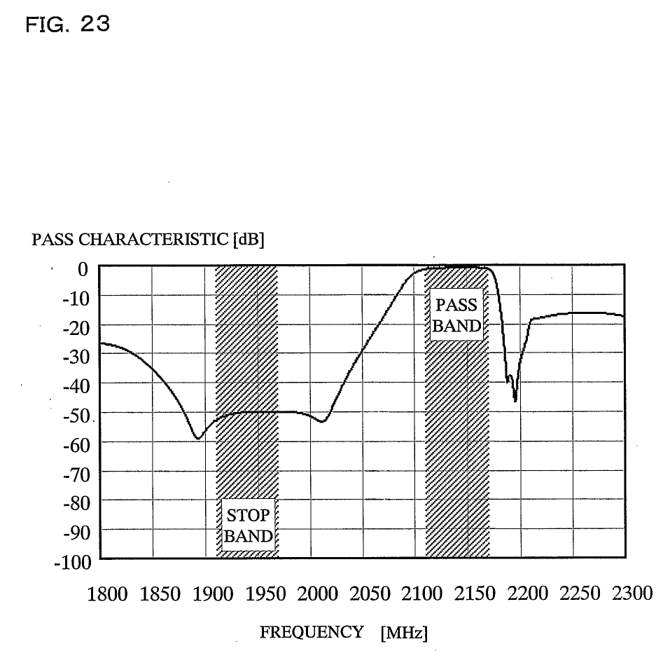

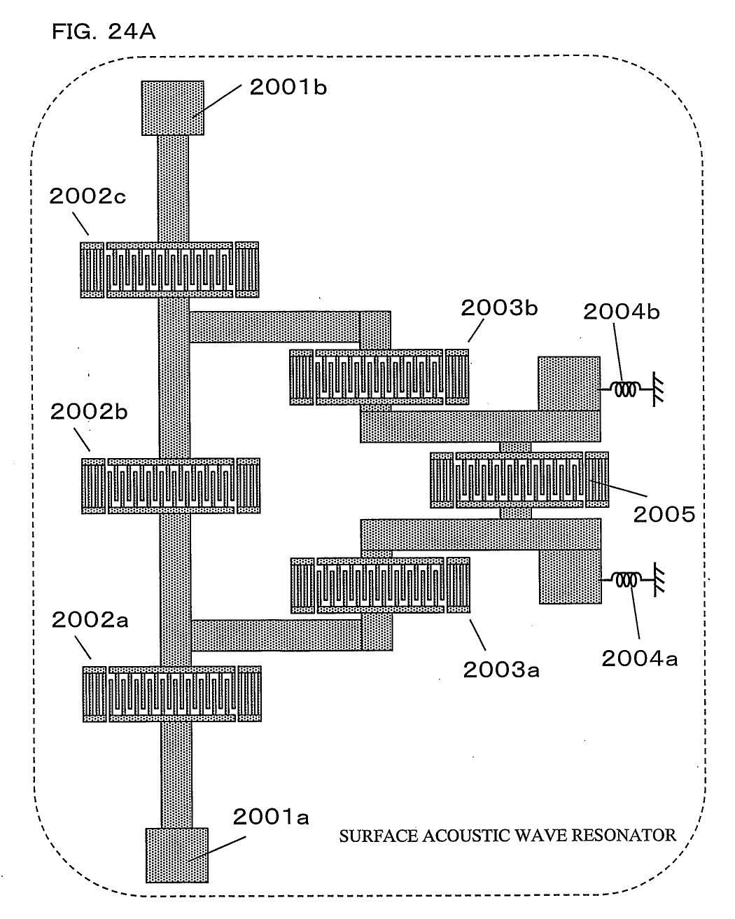

FIG. 21A is a graph indicating reflection characteristics (amplitude change versus frequency), where the input terminal 2001a has a characteristic impedance of 50 ohms. FIG. 21B is a Smith chart indicating reflection characteristics, where the input terminal 2001a has a characteristic impedance of 150 ohms (normalized with 150 ohms). FIG. 22A is a graph indicating reflection characteristics (amplitude change versus frequency), where the output terminal 2001b has a characteristic impedance of 150 ohms. FIG. 22B is a Smith chart indicating reflection characteristics, where the output terminal 2001b has a characteristic impedance of 150 ohms (normalized with 150 ohms) FIG. 23 is a graph indicating pass characteristics of the piezoelectric filter 6. In FIGS. 21A, 21B, 22A, 22B, and 23, the above-described sixth set values are used.

In the Smith charts of FIGS. 21B and 22B, markers 2101 and 2201 each indicate an impedance at 2110 MHz (the lower end of the pass band of the receiver of UMTS), markers 2102 and 2202 each indicate an impedance at 2170 MHz (the higher end of the pass band of the receiver of UMTS), and markers 2103 and 2203 each indicate an impedance at 2140 MHz (the center of the pass band of the receiver of UMTS).

As illustrated in FIGS. 21A, 21B, 22A, 22B, and 23, the capacitance Cp1 of the first parallel piezoelectric resonator 2003a is larger than the capacitance Cp2 of the second parallel piezoelectric resonator 2003b. Thereby, filter characteristics are achieved such that, within the pass band (2110 to 2170 MHz), an impedance is substantially matched to 50 ohms at the input terminal 2001a, and an impedance is substantially matched to 150 ohms at the output terminal 2001b, and a signal is transmitted with a low loss, and within the stop band (1920 to 1980 MHz), a signal is significantly attenuated.

Thus, according to the sixth embodiment, the present invention can be applied to not only a transmitting filter connected to a rear stage with respect to a power amplifier, but also a receiving filter connected to a front stage with respect to an LNA (Low Noise Amplifier).

An exemplary design procedure when the present invention is applied to a receiving filter will be described as follows. When the present invention is applied to a receiving filter, a piezoelectric filter is designed so that an output impedance of the receiving filter is conjugate to an input impedance of an LNA. After an output impedance of the piezoelectric filter is determined, the equivalent circuit constant is set to be an appropriate value, thereby producing a Smith chart normalized with the input impedance and a Smith chart normalized with the output impedance. In these Smith charts, if the reflectance is close to zero in a desired pass band and is large in a desired stop band, the equivalent circuit constant thus set is considered to be appropriate.

If the reflectance is not close to zero in the desired pass band and is not large in the stop band, the equivalent circuit constant thus set is not considered to be appropriate. Therefore, a new equivalent circuit constant is set to produce a Smith chart in a similar manner, and the reflectance is observed. If an equivalent circuit constant with which an appropriate reflectance can be obtained is obtained in this manner, a piezoelectric filter employing the equivalent circuit constant can have desired input and output impedances, and low loss and high attenuation characteristics within the desired pass and stop bands. The equivalent circuit constant is selected so that the capacitances of the parallel piezoelectric resonators in the piezoelectric filter are successively decreased toward the output terminal in order of distance from the input terminal (smallest first).

The piezoelectric filter of the present invention can be applied to a receiving filter in other communications systems as well as UMTS.

As can be seen in the fourth to sixth embodiments, the present invention is not limited to a ladder-type filter circuit.

Although a transmitting filter or a receiving filter used in the PCS or UMTS communications system is provided in the above-described embodiments, the present invention can be applied to other communications systems as well as PCS and UMTS. How to apply the present invention to communications systems other than PCS and UMTS is a matter of design choice.

### Seventh Embodiment

In a seventh embodiment, a piezoelectric filter in which a surface acoustic wave resonator is used instead of a piezoelectric resonator, will be described. The piezoelectric filter according to the seventh embodiment has an equivalent circuit similar to that of the sixth embodiment, and therefore, FIG. 20 is referenced again.

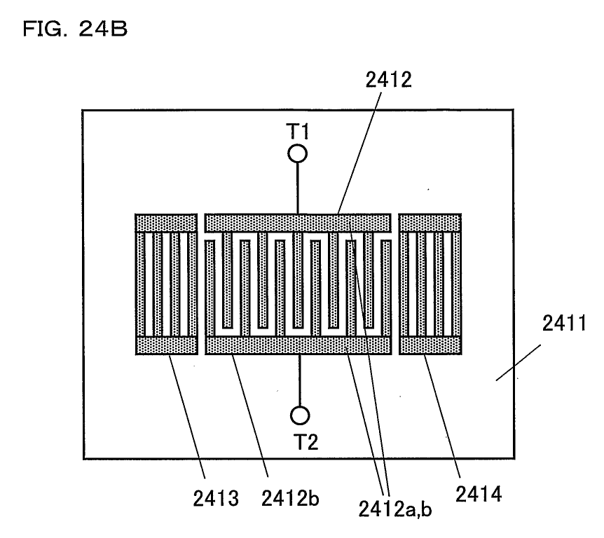

FIG. 24A is a diagram illustrating a structure of a piezoelectric filter which employs a surface acoustic wave resonator and has the equivalent circuit of FIG. 20. In FIG. 24A, parts having similar functions to those of corresponding elements of FIG. 20 are indicated with the same reference numerals.

The surface acoustic wave resonator is formed by providing an interdigital transducer (IDT) electrode and a reflector electrode on a piezoelectric substrate, these electrode being close to each other in a transmission direction. FIG. 24B is a diagram illustrating a structure of the surface acoustic wave resonator. In FIG. 24B, the surface acoustic wave resonator includes an IDT electrode 2412 composed of a comb electrode, and reflector electrodes 2413 and 2414, on a piezoelectric substrate 2411, the reflector electrodes 2413 and 2414 being provided on both sides of the IDT electrode 2412. A wave excited by the IDT electrode 2412 is confined by the reflector electrodes 2413 and 2414, thereby achieving an energy confinement resonator. Here, comb electrodes 2412a and 2412b constituting the IDT electrode 2412 correspond to input and output electrodes of the surface acoustic wave resonator itself. The piezoelectric substrate 2411 is formed of LiTaO₃, LiNbO₃, rock crystal, or the like. The IDT electrode 2412 and the reflector electrodes 2413 and 2414 are formed of Al, Ti, Cu, Al—Cu, or the like. Particularly, when applied to a transmitting filter, the IDT electrode 2412 is preferably formed of an electrode material having a high power handling capability.

In the seventh embodiment, it is assumed that the piezoelectric filter has the same equivalent circuit constant as that in the sixth set values. Note that, a resonance frequency of the surface acoustic wave resonator is optimized so as to obtain desired filter characteristics by adjusting an electrode interdigital pitch, a metallization ratio, an electrode thickness, or the like.

Thus, even when a surface acoustic wave resonator is used in a piezoelectric filter, an effect similar to that of the sixth embodiment can be obtained. In other words, the piezoelectric resonator is not limited to a thin film piezoelectric resonator as illustrated in FIG. 2, and may be a surface acoustic wave resonator.

Also in the first to fifth embodiments, when the piezoelectric resonator is replaced with a surface acoustic wave resonator, a similar effect is obtained.

The piezoelectric resonator of the present invention may comprise one or more series piezoelectric resonators connected in series between the input terminal and the output terminal, and two or more parallel piezoelectric resonators connected in parallel between the input terminal and the output terminal.

In the first to seventh embodiments, as an example, the number of parallel piezoelectric resonators in the piezoelectric filter is assumed to be three. Therefore, the first parallel piezoelectric resonator close to the input terminal is a parallel piezoelectric resonator closest to the input terminal. The second parallel piezoelectric resonator close to the output terminal is a parallel piezoelectric resonator closest to the output terminal. However, when the number of parallel piezoelectric resonators is four or more, the first parallel piezoelectric resonator close to the input terminal is not necessarily the parallel piezoelectric resonator closest to the input terminal, and the second parallel piezoelectric resonator close to the output terminal is not necessarily the parallel piezoelectric resonator closest to the output terminal.

In the present invention, if a condition that the capacitance of the first parallel piezoelectric resonator close to the input terminal is larger than the capacitance of the second parallel piezoelectric resonator close to the output terminal, is satisfied, the input and output impedances can be caused to be different from each other. Therefore, in the present invention, the first parallel piezoelectric resonator is not limited to the parallel piezoelectric resonator closest to the input terminal. Also, the second parallel piezoelectric resonator is not limited to the parallel piezoelectric resonator closest to the output terminal. The same is true of series piezoelectric resonators. Specifically, if a condition that the capacitance of the first series piezoelectric resonator close to the input terminal is larger than the capacitance of the second series piezoelectric resonator close to the output terminal, is satisfied, the effect of the present invention is obtained.

### Eighth Embodiment

In an eighth embodiment, a duplexer which employs a piezoelectric filter according to the first to seventh embodiments will be described.

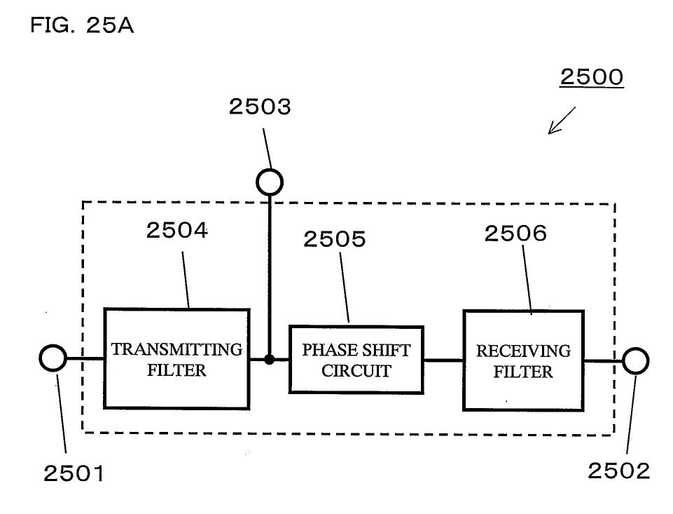

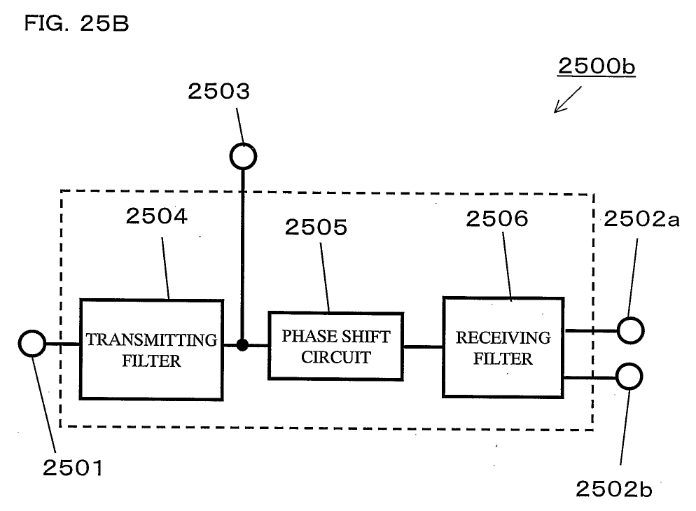

FIG. 25A is a block diagram illustrating a duplexer 2500 according to the eighth embodiment. In FIG. 25A, the duplexer 2500 comprises a transmitting terminal 2501, a receiving terminal 2502, an antenna terminal 2503, a transmitting filter 2504, a phase shift circuit 2505, and a receiving filter 2506.

The transmitting filter 2504, the phase shift circuit 2505, and the receiving filter 2506 are successively provided between the transmitting terminal 2501 and the receiving terminal 2502. The antenna terminal 2503 is connected between the transmitting filter 2504 and the phase shift circuit 2505.

At least one of the transmitting filter 2504 and the receiving filter 2506 is a piezoelectric filter according to the first to seventh embodiments.

The transmitting filter may be designed based on the characteristic impedance on the antenna terminal 2503 side and the characteristic impedance on the transmitting terminal 2501 side, as described in the first to seventh embodiments.

The receiving filter may be designed based on the characteristic impedance on the antenna terminal 2503 side and the characteristic impedance on the transmitting terminal 2501 side, as described in the first to seventh embodiments.

Note that the duplexer employing the piezoelectric filter of the eighth embodiment may have a structure as shown in FIG. 25B. FIG. 25B is a block diagram illustrating a structure of a duplexer 2500b according to the eighth embodiment. In FIG. 25B, the duplexer 2500b comprises a receiving terminal 2502a and a receiving terminal 2502b instead of the receiving terminal 2502.

The duplexer 2500b employs a piezoelectric filter of the first to seventh embodiments as the transmitting filter 2504 or the receiving filter 2506, thereby making it possible to achieve a high-impedance output. Therefore, the duplexer 2500b can easily achieve a balance output, resulting in an oscillator robust against noise.

### Ninth Embodiment

In a ninth embodiment, a communications apparatus which employs a piezoelectric filter according to the first to seventh embodiments, will be described.

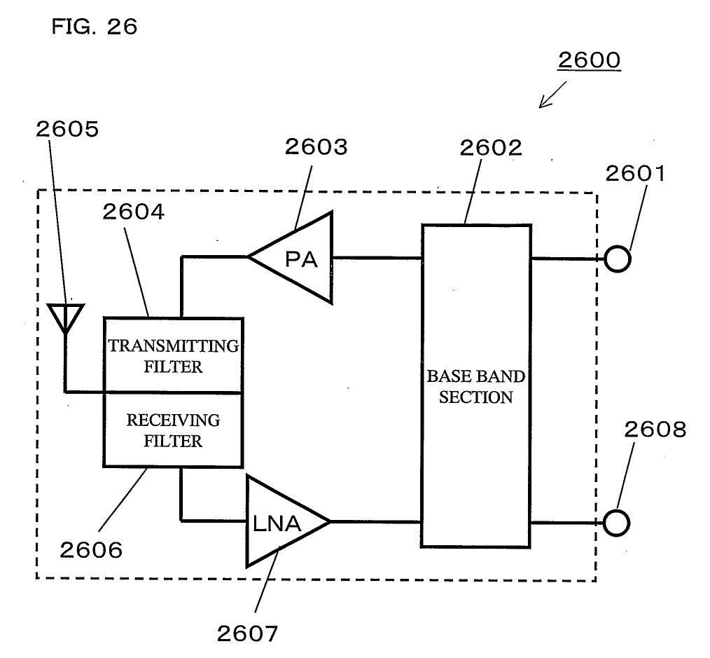

FIG. 26 is a block diagram illustrating a structure of a communications apparatus 2609 according to the ninth embodiment. In FIG. 26, the communications apparatus 2609 comprises a transmitting terminal 2601, a base band section 2602, a power amplifier 2603, a transmitting filter 2604, an antenna 2605, a receiving filter 2606, an LNA 2607, and a receiving terminal 2608.

A signal input through the transmitting terminal 2601 is transferred through the base band section 2602, is amplified by the power amplifier 2603, is filtered by the transmitting filter 2604, and is transmitted as a radio wave from the antenna 2605. A signal received by the antenna 2605 is filtered by the receiving filter 2606, is amplified by the LNA 2607, and is transferred through the base band section 2602 to the receiving terminal 2608.

At least one of the transmitting filter 2604 and the receiving filter 2606 is a piezoelectric filter according to the first to seventh embodiments.

Specifically, the transmitting filter 2604 of the communications apparatus 2609 is a piezoelectric filter whose input impedance is conjugate to an output impedance of the power amplifier 2603, and whose output impedance is conjugate to an impedance on the antenna 2605 side. The piezoelectric filter includes one or more series piezoelectric resonators connected in series between an output side of the power amplifier 2603 and the antenna 2605, and two ore more parallel piezoelectric resonators connected in parallel between the output side of the power amplifier 2603 and the antenna 2605, as in the first to seventh embodiments. Among the two or more parallel piezoelectric resonators, on an equivalent circuit, a capacitance of a first parallel piezoelectric resonator close to the power amplifier 2603 side is larger than a capacitance of a second parallel piezoelectric resonator close to the antenna 2605 side.

The receiving filter 2606 of the communications apparatus 2609 is a piezoelectric filter whose input impedance is conjugate to an impedance on the antenna 2605 side, and whose output impedance is an input impedance of the LNA 2607. The piezoelectric filter includes one or more series piezoelectric resonators connected in series between the antenna 2605 and an input side of the LNA 2607, and two or more parallel piezoelectric resonators connected in parallel between the antenna 2605 and the LNA 2607, as in the first to seventh embodiments. Among the two or more parallel piezoelectric resonators, on the equivalent circuit, a capacitance of a first parallel piezoelectric resonator close to the antenna 2605 side is larger than a capacitance of a second parallel piezoelectric resonator close to the LNA 2607 side.

Here, both of the transmitting filter 2604 and the receiving filter 2606 are assumed to be piezoelectric filters according to the first to seventh embodiments.

In general, a characteristic impedance on the antenna 2605 side is 50 ohms. A characteristic on the power amplifier 2603 side is smaller than 50 ohms. A characteristic impedance on the input side of the LNA 2607 is larger than 50 ohms. In the case of conventional communications circuits, a matching circuit needs to be provided between a power amplifier and a transmitting filter, and a matching circuit needs to be provided between an LNA and a receiving filter.

However, in the communications apparatus 2609, a piezoelectric filter according to the first to seventh embodiments is employed as the transmitting filter 2604, and therefore, the characteristic impedance on the antenna 2605 side can be caused to be 50 ohms, and the characteristic impedance on the power amplifier 2603 side can be caused to be smaller than 50 ohms (e.g., 5 ohms or 10 ohms), and it is possible to pass a transmission band and block a reception band. In addition, in the communications apparatus 2609, a piezoelectric filter according to the first to seventh embodiments is employed as the receiving filter 2606, and therefore, the characteristic impedance on the antenna 2605 side can be caused to be 50 ohms, and the characteristic impedance on the LNA 2607 side can be caused to be larger than 50 ohms (e.g., 150 ohms), and it is possible to pass a reception band and block a transmission band.

Therefore, according to the ninth embodiment, a matching circuit does not need to be provided, so that a small-size communications apparatus is provided.

Although, in the ninth embodiment, the piezoelectric filter of the present invention is provided at a rear stage with respect to the power amplifier 2603 or at a front stage with respect to the LNA 2607, a location where the piezoelectric filter is provided is not limited to these.

### Tenth Embodiment

In a tenth embodiment, a communications apparatus different from that of the ninth embodiment will be described.

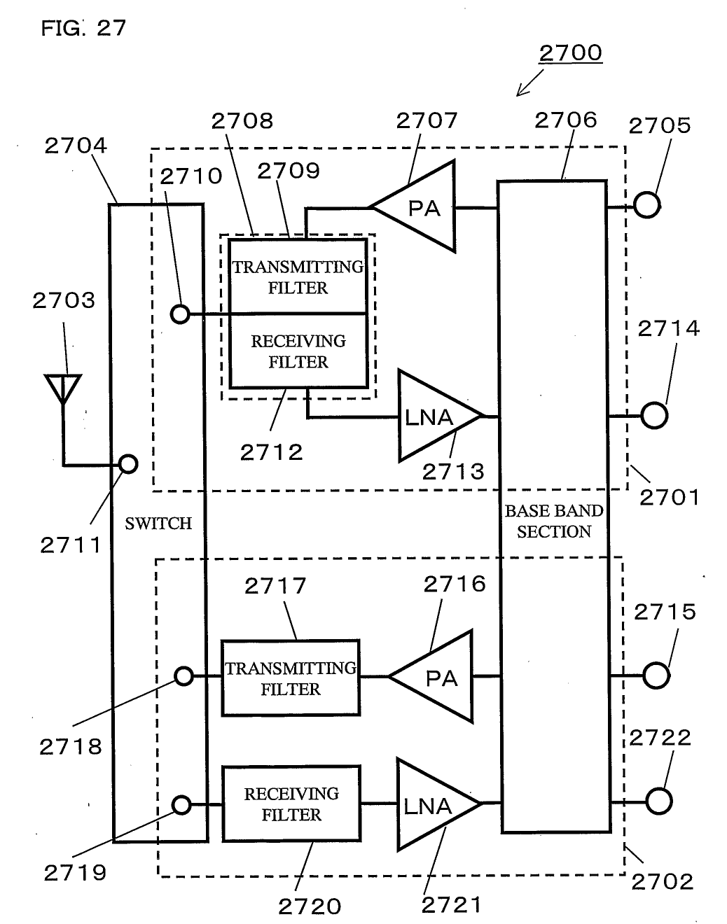

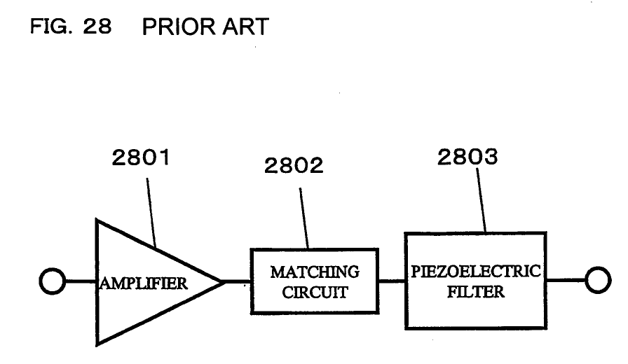

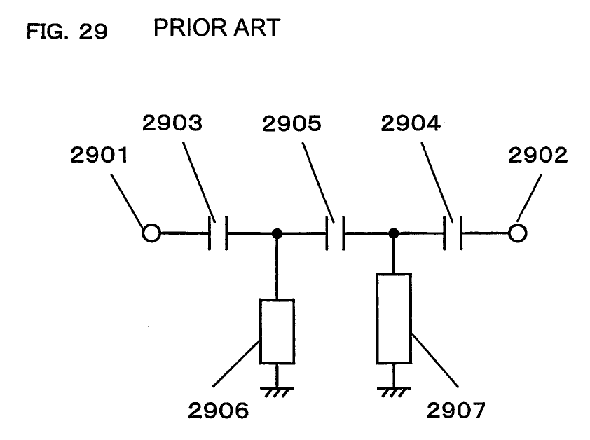

FIG. 27 is a block diagram illustrating a structure of a communications apparatus 2700 according to the tenth embodiment. In FIG. 27, in the communications apparatus 2700, a radio block which simultaneously performs transmission and reception, and a radio block which temporally switches transmission and reception, coexist. An operation of the communications apparatus 2700 of the tenth embodiment will be described, where a UMTS (Universal Mobile Telecommunications System) radio block 2701 is used as the radio block which simultaneously performs transmission and reception, and a GSM (Global System for Mobile Communications) radio block 2702 is used as the radio block which temporally switches transmission and reception.

On an antenna 2703 side, the radio blocks 2701 and 2702 are separated by a switch 2704. Also, transmission and reception of the GSM radio block 2702 are separated by the switch 2704.

In a UMTS transmitting system, a signal input from a transmitting terminal 2705 is passed through a base band section 2706, is amplified in a power amplifier 2707, is filtered through a transmitting filter 2709 included in a duplexer 2708, is passed through a UMTS transmitting/receiving terminal 2710 and an antenna terminal 2711 formed in the switch 2704, and is transmitted as electric wave from an antenna 2703. In a UMTS receiving system, a signal received from the antenna 2703 is passed through the antenna terminal 2711 and the UMTS transmitting/receiving terminal 2710, is filtered through a receiving filter 2712 included in the duplexer 2708, is amplified by an LNA 2713, and is transferred through the base band section 2706 to a receiving terminal 2714.

Similarly, in a GSM transmitting system, a signal input from a transmitting terminal 2715 is passed through the base band section 2706, is amplified in a power amplifier 2716, is filtered through a transmitting filter 2717, is passed through a GSM transmitting terminal 2718 and the antenna terminal 2711 formed in the switch 2704, and is transmitted as electric wave from the antenna 2703. In a GSM receiving system, a signal received from the antenna 2703 is passed through the antenna terminal 2711 and a GSM receiving terminal 2719, is filtered through a receiving filter 2720, is amplified by an LNA 2721, and is transferred through the base band section 2706 to a receiving terminal 2722.

At least one of the transmitting filter 2709, the receiving filter 2712, the transmitting filter 2717, and the receiving filter 2720 is a piezoelectric filter 2720 of the first to seventh embodiments. Thereby, according to the tenth embodiment, the matching circuit can be omitted, thereby providing a small-size communications apparatus.

Although, in the tenth embodiment, the piezoelectric filter of the present invention is used on a rear stage of the power amplifiers 2707 and 2716 or on a front stage of the LNAs 2713 and 2721, a portion where the piezoelectric filter is used is not limited to this.

These and other objects, features, aspects and advantages of the present invention will become more apparent from the following detailed description of the present invention when taken in conjunction with the accompanying drawings.

### INDUSTRIAL APPLICABILITY

The piezoelectric filter of the present invention has a small size, and a high attenuated amount within a desired stop band and low loss characteristics within a pass band, and therefore, is useful as a filter or the like in a radio circuit of a mobile communications terminal, such as a mobile telephone, a wireless LAN, or the like. The piezoelectric filter of the present invention can also be applied to an application, such as a filter for a radio station, depending on the specification.

1. A piezoelectric filter comprising:
an input terminal;
an output terminal;
one or more series piezoelectric resonators connected in series between the input terminal and the output terminal; and
two or more parallel piezoelectric resonators connected in parallel between the input terminal and the output terminal,
wherein, among the two or more parallel piezoelectric resonators, on an equivalent circuit, a capacitance of a first parallel piezoelectric resonator closest to the input terminal side is larger than a capacitance of a second parallel piezoelectric resonator closest to the output terminal side.

2. The piezoelectric filter according to claim 1, wherein the two or more parallel piezoelectric resonators have capacitances which are successively decreased toward the output terminal side in order of distance from the input terminal side, smallest first, on an equivalent circuit.

3. The piezoelectric filter according to claim 1, wherein:
the number of the series piezoelectric resonators is two or more; and
among the two or more series piezoelectric resonators, on an equivalent circuit, a capacitance of a first series piezoelectric resonator closest to the input terminal side is larger than a capacitance of a second series piezoelectric resonator closest to the output terminal side.

4. A duplexer comprising:
an antenna terminal;
a transmitting side terminal;
a receiving side terminal;
a transmitting filter connected between the antenna terminal and the transmitting side terminal; and
a receiving filter connected between the antenna terminal and the receiving side terminal,
wherein at least one of the transmitting filter and the receiving filter is a piezoelectric filter in which an input impedance is smaller than an output impedance, and
the piezoelectric filter comprises:
an input terminal;
an output terminal;
one or more series piezoelectric resonators connected in series between the input terminal and the output terminal; and
two or more parallel piezoelectric resonators connected in parallel between the input terminal and the output terminal,
wherein, among the two or more parallel piezoelectric resonators, on an equivalent circuit, a capacitance of a first parallel piezoelectric resonator closest to the input terminal side is larger than a capacitance of a second parallel piezoelectric resonator closest to the output terminal side.

5. A communications apparatus comprising:
a transmitting-side power amplifier;
an antenna; and
a transmitting filter connected between the antenna and the power amplifier,
wherein the transmitting filter is a piezoelectric filter whose input impedance is conjugate to an output impedance of the power amplifier, and whose output impedance is conjugate to an impedance on the antenna side, and
the piezoelectric filter comprises:
one or more series piezoelectric resonators connected in series between an output side of the power amplifier and the antenna; and
two or more parallel piezoelectric resonators connected in parallel between the output side of the power amplifier and the antenna,
wherein, among the two or more parallel piezoelectric resonators, on an equivalent circuit, a capacitance of a first parallel piezoelectric resonator closest to the power amplifier side is larger than a capacitance of a second parallel piezoelectric resonator closest to the antenna side.

6. A communications apparatus comprising:
a receiving-side low-noise amplifier;
an antenna; and
a receiving filter connected between the antenna and the low-noise amplifier,
wherein the receiving filter is a piezoelectric filter whose input impedance is conjugate to an impedance of the antenna side, and whose output impedance is conjugate to an input impedance of the low-noise amplifier, and
the piezoelectric filter comprises:
one or more series piezoelectric resonators connected in series between the antenna and an input side of the low-noise amplifier; and
two or more parallel piezoelectric resonators connected in parallel between the antenna and the input side of the low-noise amplifier,
wherein, among the two or more parallel piezoelectric resonators, on an equivalent circuit, a capacitance of a first parallel piezoelectric resonator closest to the antenna side is larger than a capacitance of a second parallel piezoelectric resonator closest to the low-noise amplifier side.
